(19) United States
(12) Patent Application Publication
(10) Pub. No.: US 2026/0018129 A1
(43) Pub. Date: Jan. 15, 2026

(54) DISPLAY DEVICE AND DRIVING METHOD THEREOF

(71) Applicant: LG Display Co., Ltd., Seoul (KR)

(72) Inventors: Intae KO, Paju-si (KR); Sangmoo SONG, Paju-si (KR); Jinuk LEE, Paju-si (KR)

(73) Assignee: LG Display Co., Ltd., Seoul (KR)

(21) Appl. No.: 19/227,071

(22) Filed: Jun. 3, 2025

(30) Foreign Application Priority Data
Jul. 15, 2024 (KR) 10-2024-0092840

(51) Int. Cl. G09G 3/3233; H10K 59/80

(52) U.S. Cl. CPC G09G 3/3233; G09G 2300/0842; G09G 2300/0861; G09G 2310/0291; G09G 2310/0297; G09G 2310/08; G09G 2320/068; G09G 2358/00; G09G 2380/10; H10K 59/879

(57) ABSTRACT

Disclosed is a display device, including: a display panel on which a plurality of pixels being disposed; a data driver configured to provide a data voltage to the plurality of pixels through a plurality of data lines; and a multiplexer connected between the data driver and the plurality of data lines and configured with a plurality of switching elements controlled by a plurality of mux control signals, and each of the plurality of pixels may include: a first sub-pixel configured to display a first image; and a second sub-pixel configured to display a same color as the first sub-pixel and to display a second image different from the first image, and a method for driving the same.

### CROSS-REFERENCE TO RELATED APPLICATION

The present application claims priority to Korea Patent Application No. 10-2024-0092840, filed Jul. 15, 2024, the entire contents of which is incorporated herein for all purposes by this reference.

### BACKGROUND

### Technical Field

The present disclosure relates to a display device and a method for driving the same.

### Description of the Related Art

As information society has developed, various types of display devices have been developed. Recently, various display devices such as a liquid crystal display (LCD), a plasma display panel (PDP), and an organic light emitting display (OLED) have been utilized.

A typical display device does not limit a viewing angle. However, the limitation of the viewing angle of the display device is recently required for the reasons of privacy and information protection. For example, in the case of a display device used as an information medium inside a vehicle, a high-definition image is provided to a passenger in a passenger seat, but a viewing angle needs to be limited to a driver for safety while traveling.

### BRIEF SUMMARY

The embodiments provide a display device capable of displaying each independent image in a plurality of regions on a display panel thereof and a method for driving the display device.

The embodiments provide a display device capable of separately displaying a privacy image and a shared image in a plurality of regions on a display panel thereof and a method for driving the display device.

The embodiments provide a display device disposing a plurality of sub-pixels in one pixel region and capable of controlling each of the sub-pixels to display an independent image and a method for driving the display device.

The embodiments provide a display device including a multiplexer and a data driver configured to output one among a privacy image or a shared image to sub-pixels in response to a mux control signal and a method for driving the display device.

The embodiments provide a display device which effectively controls a viewing angle of a displayed image and a method for driving the display device.

One embodiment is a display device, including: a display panel on which a plurality of pixels being disposed; a data driver configured to provide a data voltage to the plurality of pixels through a plurality of data lines; and a multiplexer connected between the data driver and the plurality of data lines and configured with a plurality of switching elements controlled by a plurality of mux control signals.

Each of the plurality of pixels may include: a first sub-pixel configured to display a first image; and a second sub-pixel configured to display a same color as the first sub-pixel and to display a second image different from the first image.

The data driver may include: an output buffer configured to output the data voltage to an output channel, and the multiplexer may include: a first switching element configured to be turned on in response to a first mux control signal and connect the output channel to the first sub-pixel; and a second switching element configured to be turned on in response to a second mux control signal and connect the output channel to the second sub-pixel.

The output buffer may output a first data voltage corresponding to the first image in synchronization with the first mux control signal while the pixel is operated in a first mode; and the output buffer may output a second data voltage corresponding to the second image in synchronization with the second mux control signal while the pixel is operated in a second mode.

The output buffer may output a dummy data voltage in synchronization with the second mux control signal while the pixel is operated in the first mode, and the output buffer may output the dummy data voltage in synchronization with the first mux control signal while the pixel is operated in the second mode.

The data driver may include: a first output buffer configured to output a first data voltage corresponding to the first image to a first output channel; and a second output buffer configured to output a second data voltage corresponding to the second image to a second output channel, the first output channel may be connected to the first sub-pixel, and the second output channel may be connected to the second sub-pixel.

The first output buffer may output a first data voltage corresponding to the first image to the first sub-pixel while the pixel is operated in a first mode, and the second output buffer may output a second data voltage corresponding to the second image to the second sub-pixel while the pixel is operated in a second mode.

The first output buffer may output a dummy data voltage to the first sub-pixel while the pixel is operated in the first mode, and the first output buffer may output the dummy data voltage to the second sub-pixel while the pixel is operated in the second mode.

The multiplexer may include: a first switching element configured to be turned on in response to a first mux control signal and connect the first output channel to the first sub-pixel; and a second switching element configured to be turned on in response to the first mux control signal and connect the second output channel to the second sub-pixel.

The display panel may include: a first unit pixel and a second unit pixel, each of which including two or more pixels.

The multiplexer may include: a first switching element configured to be turned on in response to a first mux control signal and connect the first output channel to the first sub-pixel of the first unit pixel; a second switching element configured to be turned on in response to the first mux control signal and connect the second output channel to the second sub-pixel of the first unit pixel; a third switching element configured to be turned on in response to a second mux control signal and connect the first output channel to the second sub-pixel of the second unit pixel; and a fourth switching element configured to be turned on in response to the second mux control signal and connect the second output channel to the second sub-pixel of the second unit pixel.

The display panel may include: a first region in which the first image is displayed through the first sub-pixel of the plurality of pixels; and a second region in which the second image is displayed through the second sub-pixel of the plurality of pixels, and the first region and the second region may vary while the display panel is driven.

In the first region, the second sub-pixel may output a dummy image, and in the second region, the first sub-pixel may output the dummy image.

The first sub-pixel and the second sub-pixel may have a same pixel structure, and the first sub-pixel and the second sub-pixel may have a form mirrored along a pixel column direction.

The display device may further include: a lens member disposed on the display panel and including a plurality of lenses, and the lens member may include: a first lens disposed in a first light emitting region of the first sub-pixel; and a second lens disposed in a second light emitting region of the second sub-pixel and having a form different from the first lens.

The first lens may control a light emitted from the first light emitting region to be emitted at a first viewing angle, and the second lens may control a light emitted from the second light emitting region to be emitted at a second viewing angle.

Another embodiment is a method for driving a display device, including: allowing the data driver to output a first data voltage corresponding to the first image to the first sub-pixel; and allowing the data driver to output a second data voltage corresponding to the second image to the second sub-pixel.

The outputting a first data voltage may include: allowing the multiplexer to connect a first output channel to the first sub-pixel in response to a first mux control signal in a first period of one horizontal period; allowing the data driver to output the first data voltage in synchronization with the first mux control signal in the first period; allowing the multiplexer to connect the first output channel to the second sub-pixel in response to a second mux control signal in a second period of the one horizontal period; and allowing the data driver to output a dummy data voltage in synchronization with the second mux control signal in the second period.

The outputting a second data voltage may include: allowing the multiplexer to connect a first output channel to the first sub-pixel in response to a first mux control signal in a first period of one horizontal period; allowing the data driver to output the dummy data voltage in synchronization with the first mux control signal in the first period; allowing the multiplexer to connect the first output channel to the second sub-pixel in response to a second mux control signal in a second period of the one horizontal period; and allowing the data driver to output the second data voltage in synchronization with the second mux control signal in the second period.

The outputting a first data voltage may include: allowing the multiplexer to connect a first output channel to the first sub-pixel of the first unit pixel in response to a first mux control signal in a first period of one horizontal period; and allowing the data driver to output the first data voltage to the first output channel in synchronization with the first mux control signal in the first period, and the outputting a second data voltage may include: allowing the multiplexer to connect the second output channel to the second sub-pixel of the first unit pixel in response to the first mux control signal in the first period; and allowing the data driver to output the second data voltage to the second output channel in synchronization with the first mux control signal in the first period.

The outputting a first data voltage may include: allowing the multiplexer to connect a first output channel to the first sub-pixel of the second unit pixel in response to a second mux control signal in a second period of the one horizontal period; and allowing the data driver to output the first data voltage to the first output channel in synchronization with the second mux control signal in the second period, and the outputting a second data voltage may include: allowing the multiplexer to connect the second output channel to the second sub-pixel of the second unit pixel in response to the second mux control signal in the second period; and allowing the data driver to output the second data voltage to the second output channel in synchronization with the second mux control signal in the second period.

The outputting a first data voltage may include: allowing the data driver to output the first data voltage to the first sub-pixel through a first output channel in a first horizontal period, and the outputting a second data voltage may include: allowing the data driver to output the second data voltage to the second sub-pixel through a second output channel in the first horizontal period.

A display device and a method for driving the display device according to the embodiments may easily and freely vary a size and a shape of regions in which a privacy image and a shared image are displayed.

A display device and a method for driving the display device according to the embodiments may improve an output delay and image quality deterioration caused by an image changeover by allocating output buffers of a data driver to a privacy image or a shared image.

A display device and a method for driving the display device according to the embodiments may efficiently implement a privacy mode and a share mode in various use environments.

### BRIEF DESCRIPTION OF THE SEVERAL VIEWS OF THE DRAWINGS

FIG. 1 is a block diagram illustrating a configuration of a display device according to an embodiment.

FIG. 2 is a view illustrating a method for driving a display device according to an embodiment.

FIG. 3 is a diagram illustrating a configuration of a pixel according to an embodiment.

FIG. 4 is a block diagram illustrating a configuration of a data driver according to an embodiment.

FIG. 5 is a diagram illustrating a connection relationship between a pixel and a data driver according to a first embodiment.

FIG. 6 is a waveform diagram of control and driving signals applied to a display device of FIG. 5.

FIG. 7 is a diagram illustrating a connection relationship between a pixel and a data driver according to a second embodiment.

FIG. 8 is a waveform diagram of control and driving signals applied to a display device of FIG. 7.

FIG. 9 is a diagram illustrating a connection relationship between a pixel and a data driver according to a third embodiment.

FIG. 10 is a waveform diagram of control and driving signals applied to a display device of FIG. 9.

FIG. 11 is a circuit diagram of a pixel according to an embodiment.

FIG. 12 is a plan view illustrating a layout of a pixel illustrated in FIG. 11.

FIG. 13 is a diagram illustrating a method for driving a pixel illustrated in FIG. 11.

FIG. 14 is a plan view of a unit pixel according to an embodiment.

FIG. 15 is a view schematically illustrating a first lens illustrated in FIG. 14.

FIG. 16 is a view illustrating a light profile with respect to a viewing angle of a first lens illustrated in FIG. 15.

FIG. 17 is a view schematically illustrating a second lens illustrated in FIG. 14.

FIG. 18 is a view illustrating a light profile with respect to a viewing angle of a second lens illustrated in FIG. 17.

FIG. 19 is a cross-sectional view schematically illustrating a display region of a display panel according to an embodiment.

FIG. 20 is a cross-sectional view schematically illustrating a non-display region of a display panel according to an embodiment.

FIG. 21 is an example view of an arrangement of a display device according to an embodiment.

### DETAILED DESCRIPTION

Hereinafter, embodiments of the disclosure will be described with reference to the drawings. In this specification, when it is mentioned that a component (or, an area, a layer, a part, etc.) is referred to as being “on”, “connected to” or “combined to” another component, this means that the component may be directly on, connected to, or combined to the other component or a third component therebetween may be present.

Like reference numerals refer to like elements. Additionally, in the drawings, the thicknesses, proportions, and dimensions of components are exaggerated for effective description. “And/or” includes all of one or more combinations defined by related components.

It will be understood that the terms “first” and “second” are used herein to describe various components but these components should not be limited by these terms. The above terms are used only to distinguish one component from another. For example, a first component may be referred to as a second component and vice versa without departing from the scope of the disclosure. The singular expressions include plural expressions unless the context clearly dictates otherwise.

In addition, terms such as “below”, “the lower side”, “on”, and “the upper side” are used to describe a relationship of configurations shown in the drawing. The terms are described as a relative concept based on a direction shown in the drawing.

In various embodiments of the disclosure, the term “include,” “comprise,” “including,” or “comprising,” specifies a property, a fixed number, a step, a process, an element and/or a component, or a combination thereof, but does not exclude presence or addition of other properties, fixed numbers, steps, processes, elements and/or components, or a combination thereof.

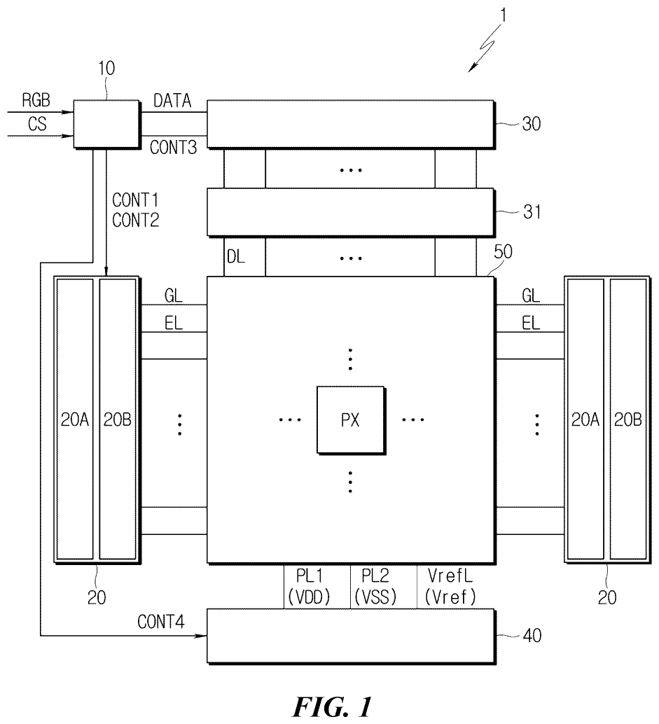

FIG. 1 is a block diagram illustrating a configuration of a display device according to an embodiment.

Referring to FIG. 1, a display device 1 according to an embodiment includes a timing controller 10, a gate driver 20, a data driver 30, a multiplexer 31, a power supply unit 40, and a display panel 50.

The timing controller 10 may receive a video signal RGB and a control signal CS from an external host system and the like. The video signal RGB may include a plurality of grayscale data. The control signal CS may include, for example, a horizontal synchronization signal, a vertical synchronization signal and a main clock signal.

The timing controller 10 processes the video signal RGB and the control signal CS to be suitable to operational conditions of the display panel 50, and may generate and output video data DATA, a gate driving control signal CONT1, an emission driving control signal CONT2, a data driving control signal CONT3, and a power supply control signal CONT4.

The gate driver 20 may include a scan driving circuit 20A configured to generate scan signals based on a gate driving control signal CONT1 input from the timing controller 10. The scan driving circuit 20A may provide the generated scan signals to the pixels PX through a plurality of scan lines GL. In an embodiment, one pixel PX may be configured to receive a plurality of scan signals having each different waveform. In such an embodiment, the scan driving circuit 20A may provide a plurality of scan signals to the pixels PX through corresponding scan lines GL, respectively.

In addition, the gate driver 20 may further include an emission driving circuit 20B configured to generate emission control signals based on the emission driving control signal CONT2. The emission driving circuit 20B may provide the generated emission control signals to the pixels PX through emission lines EL.

The gate driver 20 may be formed in a gate-in-panel manner in which the gate driver 20 is mounted in the display panel 50. The gate driver 20 may be disposed on one side of the display panel 50, or on both sides (for example, a left side and a right side) of the display panel 50 as illustrated. According to a driving method, a panel design method, and the like, the gate driver 20 may be disposed on both sides (for example, a left side and a right side) of the display panel 50 as illustrated, or may be connected to two or more side surfaces among four side surfaces of the display panel 50.

The data driver 30 may generate data voltages based on the data driving control signal CONT3 and image data DATA output from the timing controller 10. The data driver 30 may provide the generated data voltages to the pixels PX through a plurality of data lines DL.

In an embodiment, the display device 1 may include a multiplexer 31 connected between the data driver 30 and the pixels PX and configured to time-dividedly drive the data lines DL. The multiplexer 31 connects each output channel of the data driver 30 to two or more data lines DL. In addition, the multiplexer 31 may reduce a quantity of the output channels of the data driver 30 by time-dividedly distributing a data voltage output from the output channels of the data driver 30 to the data lines DL.

In an embodiment, the multiplexer 31 may include a plurality of switching elements connected between the output channel of the data driver 30 and the data lines DL. For example, the multiplexer 31 may be a 1:n multiplexer in which one output channel is connected to i (i is an integer greater than 1) data lines DL through one switching element.

The power supply unit 40 may generate a high potential driving voltage VDD and a low potential driving voltage VSS to be provided to the display panel 50 based on the power supply control signal CONT4. The power supply unit 40 may provide the generated driving voltages VDD and VSS to the pixels PX through corresponding power lines PL1 and PL2. In addition, the power supply unit 40 may further generate a reference voltage Vref required for driving the pixel PX and provide it to the pixels PX through a corresponding voltage line VrefL.

On the display panel 50, a plurality of pixels PX (or referred to as sub-pixels) may be disposed. The pixels may be disposed, for example, in a matrix form on the display panel 50. The pixels disposed in one pixel row are connected to the same scan line GL and light emission line EL, and the pixels disposed in one pixel column are connected to the same data line DL. The pixels PX may emit light at luminance corresponding to a data voltage and a scan signal supplied through the scan line GL and the data line DL in response to an emission control signal applied through the light emission line EL.

In an embodiment, each pixel PX may display one color among red, green and blue. In another embodiment, each pixel PX may display one color among cyan, magenta and yellow. In various embodiments, each pixel PX may display one color among red, green, blue and white.

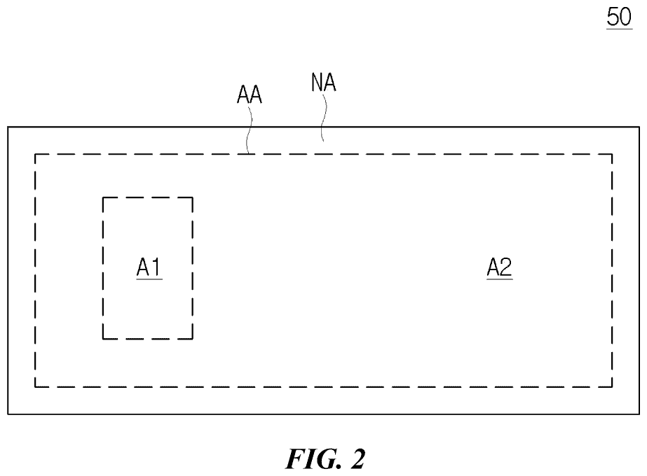

FIG. 2 is a view illustrating a method for driving a display device according to an embodiment.

Referring to FIG. 2, the display panel 50 may include a display region AA in which an image is displayed, and a non-display region NA around the display region AA. The display region AA may have generally a rectangular shape as illustrated, but is not limited thereto, and may be formed in a polygonal, circular, oval shape or a polygonal shape of which at least one edge is formed as a curve, etc. The non-display region NA is disposed to surround the display region AA, and may be formed to follow a shape of the display region AA or to have an independent shape.

The display region AA may be divided into a first region A1 and a second region A2. The first region A1 is a region which displays a first image, for example, and may be driven to display a privacy image only visible to a certain viewer. For example, in a case of a display installed in a vehicle, the viewer of the first image may be, for example, a driver, and in such a case, the first region A1 may be a region disposed adjacent to a driver's seat, but is not limited thereto.

The second region A2 is a region which displays a second image different from the first image, and may be driven to display, for example, a shared image visible to the other viewer or all viewers. Following the example of the vehicle display, the other viewer may be a fellow passenger, and in such a case, the second region A2 may be a region disposed adjacent to a front passenger's seat, but is not limited thereto.

The display panel 50 may be controlled such that the first region A1 operates in a first mode, and the second region A2 operates in a second mode. For example, the first region A1 may operate in the first mode having a narrower viewing angle than the second region A2, and the second region A2 may operate in the second mode having a wider viewing angle than the first region A1.

In other words, the first region A1 may operate in the first mode in which the viewing angle is limited so that an image is visible to only a certain viewer (for example, a driver), that is, a privacy mode, and the second region A2 may operate in the second mode in which the viewing angle is widened so that an image is visible to the other viewer or all viewers, that is, a share mode.

A size and a shape of the first region A1 and the second region A2 is not limited. In particular, in an embodiment, a size and a shape of the first region A1 and the second region A2 may vary while the display panel 50 operates. In the illustrated embodiment, the first region A1 may have a smaller area than the second region A2. However, the embodiment is not limited thereto.

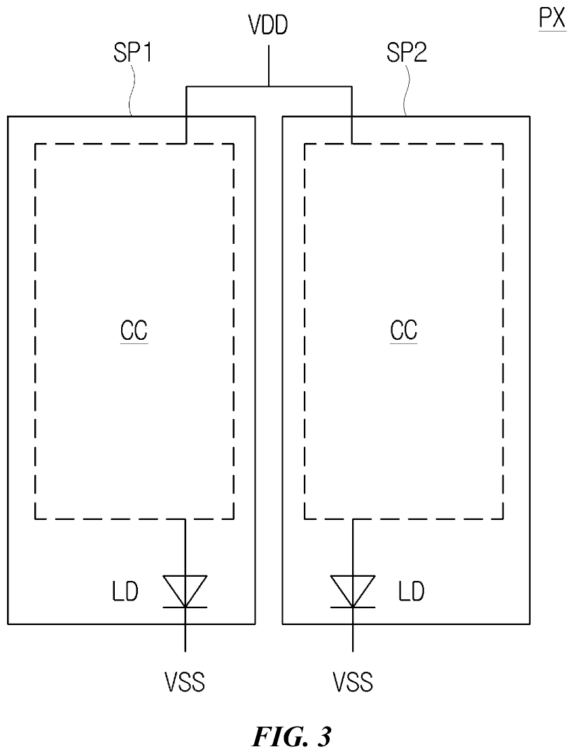

FIG. 3 is a diagram illustrating a configuration of the pixel according to an embodiment.

Referring to FIG. 3, the pixel PX according to an embodiment is configured to include a plurality of sub-pixels SP1 and SP2. For example, the pixel PX may be configured to include a first sub-pixel SP1 and a second sub-pixel SP2.

Each of the sub-pixels SP1 and SP2 may include a control circuit CC for controlling a light emitting diode LD and an amount of a drive current to be applied to the light emitting diode LD. The control circuit CC may include at least one transistor and a capacitor.

Control circuits CC of the sub-pixels SP1 and SP2 configuring one pixel PX may be configured with the same or different circuit. For example, the control circuits CC of the sub-pixels SP1 and SP2 may have the same circuit structure, and may be disposed to have a mirrored shape, but are not limited thereto.

The light emitting diode LD may be various light emitting diodes such as LED, OLED, QLED, QNED, mini-LED, micro-LED, nano-LED, and the like. Hereinafter, embodiments will be described by taking a case in which the light emitting diode LD is an OLED as an example, but the disclosed technology is not limited thereto.

The light emitting diode LD may display one color among red, green and blue. In another embodiment, the light emitting diode LD may display one color among cyan, magenta and yellow. In another embodiment, the light emitting diode LD may display one color among red, green, blue and white.

The light emitting diodes LD of the sub-pixels SP1 and SP2 of a same pixel PX may display the same color. For example, the light emitting diodes LD of the sub-pixels SP1 and SP2 included in a red pixel PX may display a red color, the light emitting diodes LD of the sub-pixels SP1 and SP2 included in a green pixel PX may display a green color, and the light emitting diodes LD of the sub-pixels SP1 and SP2 included in a blue pixel PX may display a blue color.

Three pixels PX displaying red, green, and blue, respectively, may form one unit pixel. However, the present embodiment is not limited thereto. As described above, when the pixels PX display cyan, magenta, and yellow, three pixels PX displaying cyan, magenta, and yellow, respectively, may form one unit pixel. Alternatively, when the pixels PX display red, green, blue, and white, four pixels PX displaying red, green, blue, and white, respectively, may form one unit pixel. Alternatively, two or more pixels PX displaying the same color may be included in one unit pixel.

In various embodiments, the sub-pixels SP1 and SP2 included in one pixel PX may be driven to display different images. For example, the first sub-pixel SP1 may display the first image described referring to FIG. 2, and the second sub-pixel SP2 may display the second image described referring to FIG. 2.

When the pixel PX is driven in the first mode in the first region, the first sub-pixel SP1 may be driven to display the first image, and when the pixel PX is driven in the second mode in the second region, the second sub-pixel SP2 may be driven to display the second image.

Meanwhile, when the pixel PX is driven in the first mode in the first region A1, the second sub-pixel SP2 may be driven to display a predetermined dummy image. The dummy image may be, for example, a black image, but is not limited thereto. On contrary, when the pixel PX is driven in the second mode in the second region A2, the first sub-pixel SP1 may be driven to display a predetermined dummy image.

As described above, a size and a shape of the first region A1 and the second region A2 may vary. That is, while the display device 1 (FIG. 1) is driven, the pixel PX may operate in the first mode in a first period, and may operate in the second mode in a second period. In such an embodiment, the first sub-pixel SP1 may output the first image in the first period by receiving a data voltage corresponding to the first image, and the second sub-pixel SP2 may output the second image in the second period by receiving a data voltage corresponding to the second image.

Hereinafter, detailed embodiments for allowing a data voltage corresponding to the first image and the second image to the first sub-pixel SP1 and the second sub-pixel SP2, respectively, will be described as an illustrative example.

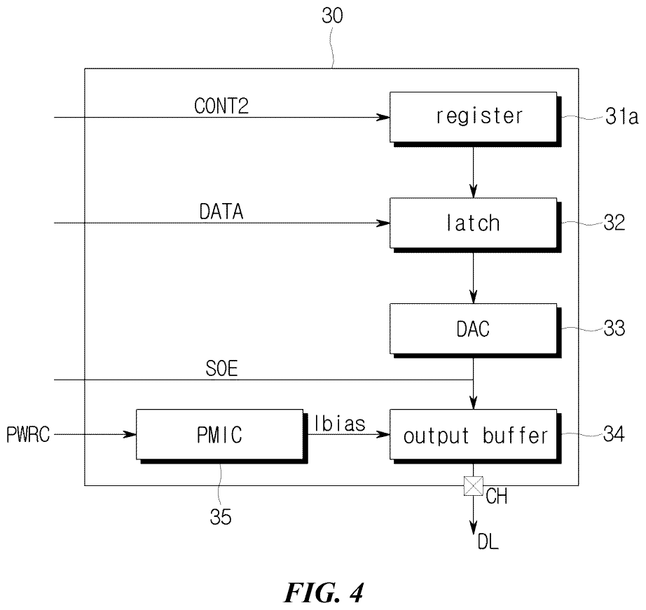

FIG. 4 is a block diagram illustrating a configuration of the data driver according to an embodiment.

Referring to FIG. 4, the data driver 30 may include a register 31a, a latch 32, a digital-to-analog converter (DAC) 33, and an output buffer 34.

The register 31a generates a sampling signal using a data driving control signal CONT2 received from the timing controller 10 (FIG. 1), and provides the generated sampling signal to the latch 32.

The latch 32 latches image data DATA received from the timing controller 10, and outputs the image data DATA to the DAC 33 in response to the sampling signal received from the register 31a.

The DAC 33 may convert the image data received from the latch 32 into a gamma compensation voltage and generate a data voltage.

The output buffer 34 outputs a data voltage output from the DAC 33 according to a source output enable signal SOE, received from the timing controller 10, to the data line DL through an output channel CH.

In an embodiment, the data driver 30 may further include a power management circuit (PMIC) 35. The PMIC 35 may generate a bias current Ibias based on a power control signal PWRC received from the timing controller 10, and apply the bias current ibias to the output buffer 34. The PMIC 35 may control a magnitude of the data voltage output from the data driver 30 and manage power consumption of the data driver 30, by varying a magnitude of the bias current Ibias according to a mode instructed by the power control signal PWRC.

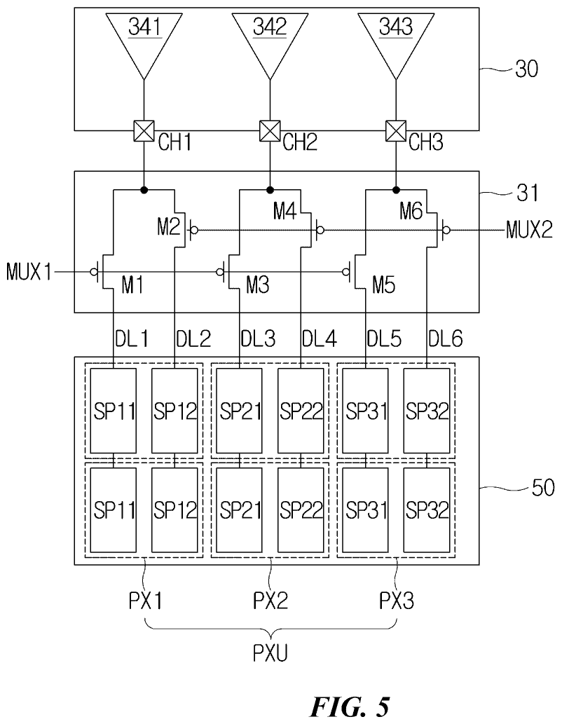

FIG. 5 is a diagram illustrating a connection relationship between the pixel and the data driver according to a first embodiment.

Referring to FIG. 5, the data driver 30 may include a plurality of output channels CH1, CH2, and CH3 connected to a plurality of output buffers 341, 342, and 343, respectively. Each of the output channels CH1, CH2, and CH3 may output a data voltage applied from the connected output buffers 342, 342, and 343.

Each of the output channels CH1, CH2, and CH3 may be connected to each of the pixels PX1, PX2, and PX3 through the multiplexer 31. For example, the first output channel CH1 may be connected to the first pixel PX1, the second output channel CH2 may be connected to the second pixel PX2, and the third output channel CH3 may be connected to the third pixel PX3.

The multiplexer 31 includes a plurality of switching elements M1, M2, M3, M4, M5, and M6. Each of the switching elements M1, M2, M3, M4, M5, and M6 may be connected to one among the output channels CH1, CH2, and CH3 of the data driver 30.

At this instance, two or more switching elements M1, M2, M3, M4, M5, and M6 may be connected to one output channel CH1, CH2, and CH3. For example, the first and second switching elements M1 and M2 may be connected to the first output channel CH1, the third and fourth switching elements M3 and M4 may be connected to the second output channel CH2, and the fifth and sixth switching elements M5 and M6 may be connected to the third output channel CH3.

Turning on and off of the switching elements M1, M2, M3, M4, M5, and M6 may be controlled through mux control signals MUX1 and MUX2 provided from the timing controller 10 (FIG. 1) and the like. In more detail, the first switching element M1, the third switching element M3, and the fifth switching element M5 are controlled in response to a first mux control signal MUX1, and the second switching element M2, the fourth switching element M4, and the sixth switching element M6 may be controlled according to a second mux control signal MUX2. Here, because the switching elements M1, M2, M3, M4, M5, and M6 are controlled by two or more mux control signals MUX1 and MUX2, the multiplexer 31 may be referred to as a 2MUX structure.

The display panel 50 includes a plurality of pixels PX1, PX2, and PX3 disposed in a matrix form. In FIG. 5, the pixels PX1, PX2, and PX3, each of which displays a first color, a second color, or a third color, respectively, are illustrated representatively. Here, the first color may be red, the second color may be green, and the third color may be blue. However, the embodiments are not limited thereto. The first to the third pixels PX1, PX2, and PX3 displaying the first to the third colors may configure one unit pixel PXU.

Each of the pixels PX1, PX2, and PX3 includes first and second sub-pixels SP11, SP12, SP21, SP22, SP31 and SP32. Each of the pixels PX1, PX2, and PX3 is driven to display the first image or the second image as described referring to FIG. 3.

The sub-pixels SP11, SP12, SP21, SP22, SP31 and SP32 are connected to corresponding data lines DL1, DL2, DL3, DL4, DL5, and DL6, and scan lines GL1 and GL2. The switching elements M1, M2, M3, M4, M5, and M6 of the multiplexer 31 are connected to an input end of the data lines DL1, DL2, DL3, DL4, DL5, and DL6, respectively.

At this instance, the sub-pixels SP11, SP12, SP21, SP22, SP31, and SP32 configuring one pixel PX1, PX2, and PX3 may be connected to one output channel CH1, CH2, and CH3 through the switching elements M1, M2, M3, M4, M5, and M6. For example, the sub-pixels SP11 and SP12 configuring the first pixel PX1 may be connected to the first output channel CH1 through the first and second switching elements M1 and M2, the sub-pixels SP21 and SP22 configuring the second pixel PX2 may be connected to the second output channel CH2 through the third and fourth switching elements M3 and M4, and the sub-pixels SP31 and SP32 configuring the third pixel PX3 may be connected to the third output channel CH3 through the fifth and sixth switching elements M5 and M6.

When the switching elements M1, M2, M3, M4, M5, and M6 are turned on in response to the mux control signal MUX1 and MUX2, a data voltage may be applied to the data lines DL1, DL2, DL3, DL4, DL5, and DL6 connected to the corresponding switching elements M1, M2, M3, M4, M5, and M6. In more detail, when the first, third, and fifth switching elements M1, M3, and M5 are turned on by the first mux control signal MUX1, a data voltage may be applied to the first sub-pixels SP11, SP21, and SP31 of each pixel PX1, PX2, and PX3 connected to the first, third, and fifth data lines DL1, DL3, and DL5. In addition, when the second, fourth, and sixth switching elements M2, M4, and M6 are turned on by the second mux control signal MUX2, a data voltage may be applied to the second sub-pixels SP12, SP22, and SP32s of each pixel PX1, PX2, and PX3 connected to the second, fourth, and sixth data lines DL2, DL4, and DL6.

In an embodiment, the switching elements M1, M2, M3, M4, M5, and M6 may be configured as a transistor. In an illustrated embodiment, the switching elements M1, M2, M3, M4, M5, and M6 are pMOS transistors. In such an embodiment, a turn-on level of the mux control signal MUX1 and MUX2 may have a low level. However, the embodiment is not limited thereto. That is, in another embodiment, the switching elements M1, M2, M3, M4, M5, and M6 may be nMOS transistors. In such an embodiment, a turn-on level of the mux control signal MUX1 and MUX2 may have a high level.

In an embodiment, the output buffers 341, 342, and 343 may output a data voltage corresponding to the first image in synchronization with the first mux control signal MUX1 in a turn-on level, and may output a data voltage corresponding to the second image in synchronization with the second mux control signal MUX2 in a turn-on level. Then, while the first mux control signal MUX1 is applied, a data voltage corresponding to the first image is applied to the first sub-pixels SP11, SP21 and SP31, and while the second mux control signal MUX2 is applied, a data voltage corresponding to the second image is applied to the second sub-pixels SP12, SP22 and SP32. Therefore, the first sub-pixels SP11, SP21 and SP31 may emit light at luminance corresponding to the first image, and the second sub-pixels SP12, SP22 and SP32 may emit light at luminance corresponding to the second image.

If the first image to be displayed in the first sub-pixels SP11, SP21 and SP31 does not exist in a certain frame (for example, the pixels PX1, PX2 and PX3 operate in the second mode in the corresponding frame), the output buffers 341, 342 and 343 may be controlled to output a predetermined dummy data voltage in synchronization with the first mux control signal MUX1 in the corresponding frame. On contrary, if the second image to be displayed in the second sub-pixels SP12, SP22 and SP32 does not exist in a certain frame (for example, the pixels PX1, PX2 and PX3 operate in the first mode in the corresponding frame), the output buffers 341, 342 and 343 may be controlled to output a predetermined dummy data voltage in synchronization with the second mux control signal MUX2 in the corresponding frame.

In the embodiment described above, the output channels CH1, CH2, and CH3 and the sub-pixels SP11, SP12, SP21, SP22, SP31, and SP32 have a connection relationship of 1:n, that is, 1:2. That is, one output channel CH1, CH2, and CH3 is connected to the first sub-pixel SP11, SP21, and SP31 and the second sub-pixel SP12, SP22, and SP32 configuring one pixel PX1, PX2, and PX3 in a 1:n relationship through the multiplexer 31.

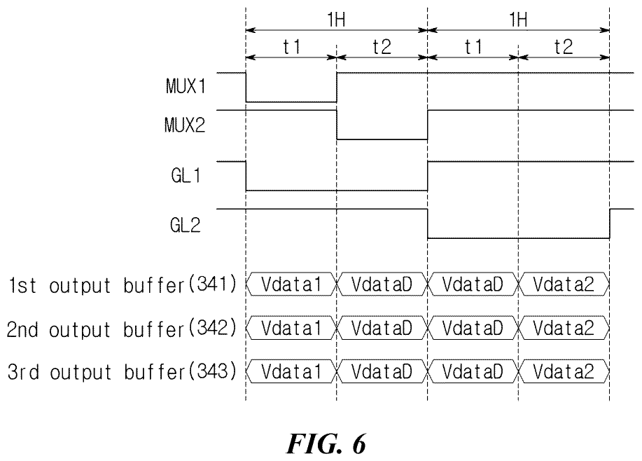

FIG. 6 is a waveform diagram of control and driving signals applied to the display device of FIG. 5. In FIG. 6, an example, in which during one illustrated frame, the pixels PX1, PX2, and PX3 in a first pixel row operate in the first mode, and the pixels PX1, PX2, and PX3 in a second pixel row operate in the second mode, is illustrated.

Referring to FIGS. 5 and 6 together, during one frame, a gate signal in a turn-on level is sequentially applied to the scan lines GL1 and GL2. At this instance, each of the gate signals may be applied in a turn-on level during one horizontal period 1H. The pixels PX1, PX2, and PX3 of the pixel row to which the gate signals in a turn-on level is applied may receive a data voltage through the data lines DL1, DL2, DL3, DL4, DL5, and DL6.

Each of the output buffers 341, 342, and 343 may output a data voltage sequentially with respect to the sub-pixels SP11, SP12, SP21, SP22, SP31, and SP32 configuring one pixel PX1, PX2, and PX3 by timing-dividing the one horizontal period 1H. For example, each of the output buffers 341, 342, and 343 may output a data voltage of the first sub-pixels SP11, SP21, and SP31 during a first period t1 of the one horizontal period 1H, and may output a data voltage of the second sub-pixels SP12, SP22, and SP 32 during a second period t2 thereof.

During the one horizontal period 1H, the timing controller 10 (FIG. 1) provides the mux control signal MUX1 and MUX2 so that the switching elements M1, M2, M3, M4, M5, and M6 of the multiplexer 31 can be turned on sequentially.

The pixels PX1, PX2, and PX3 in the first pixel row may operate in the first mode. During the first period t1 of a first one horizontal period, the first mux control signal MUX1 in a turn-on level is applied to the multiplexer 31. Then, the first, third, and fifth switching elements M1, M3, and M5 are turned on, and a data voltage Vdata1 of the first image output from the output buffers 341, 342, and 343 may be applied to each of the first sub-pixels SP11, SP21, and SP31.

During the second period t2, the second mux control signal MUX2 in a turn-on level is applied to the multiplexer 31. Then, the second, fourth, and sixth switching elements M2, M4, and M6 are turned on, and a dummy data voltage VdataD output from the output buffers 341, 342, and 343 may be applied to each of the second sub-pixels SP12, SP22, and SP32.

The pixels PX1, PX2, and PX3 in the second pixel row may operate in the second mode. During the first period t1 of the second one horizontal period, the first mux control signal MUX1 in a turn-on level is applied to the multiplexer 31. Then, the first, third, and fifth switching elements M1, M3, and M5 are turned on, and a dummy data voltage VdataD output from the output buffers 341, 342, and 343 may be applied to each of the first sub-pixels SP11, SP21, and SP31.

During the second period t2, the second mux control signal MUX2 in a turn-on level is applied to the multiplexer 31. Then, the second, fourth, and sixth switching elements M2, M4, and M6 are turned on, and a data voltage Vdata2 of the second image output from the output buffers 341, 342, and 343 may be applied to each of the second sub-pixels SP12, SP22, and SP32.

In such a manner, by allowing the image data in the first mode or the second mode to be selectively applied with respect to the pixel rows, the size, and the shape of the first region A1 (FIG. 2) in which the first image is displayed and the second region A2 (FIG. 2) in which the second image is displayed in the display panel 50 may be freely changed.

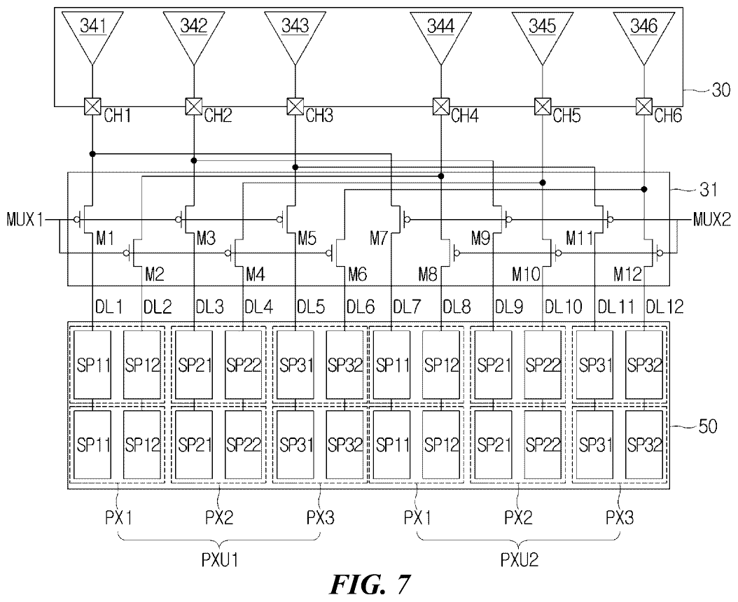

FIG. 7 is a diagram illustrating a connection relationship between a pixel and a data driver according to a second embodiment.

Referring to FIG. 7, the data driver 30 may include a plurality of output channels CH1, CH2, CH3, CH4, CH5, and CH6 connected to a plurality of output buffers 341, 342, 343, 344, 345, and 346 respectively. Each of the output channels CH1, CH2, CH3, CH4, CH5, and CH6 may output a data voltage applied from the connected output buffers 341, 342, 343, 344, 345, and 346.

Each of the output channels CH1, CH2, CH3, CH4, CH5, and CH6 may be connected to each of the pixels PX1, PX2, and PX3 of the unit pixels PXU1 and PXU2 through the multiplexer 31. For example, the first output channel CH1 and the fourth output channel CH4 may be connected to the first pixels PX1 of the unit pixels PXU1 and PXU2, the second output channel CH2 and the fifth output channel CH5 may be connected to the second pixels PX2 of the unit pixels PXU1 and PXU2, and the third output channel CH3 and the sixth output channel CH6 may be connected to the third pixels PX3 of the unit pixels PXU1 and PXU2.

The multiplexer 31 includes a plurality of switching elements M1, M2, M3, M4, M5, M6, M7, M8, M9, M10, M11, and M12. Each of the switching elements M1, M2, M3, M4, M5, M6, M7, M8, M9, M10, M11, and M12 may be connected to one among the output channels CH1, CH2, CH3, CH4, CH5, and CH6 of the data driver 30.

At this instance, two or more switching elements among the plurality of switching elements M1, M2, M3, M4, M5, M6, M7, M8, M9, M10, M11, and M12 may be connected to one output channel among the output channels CH1, CH2, CH3, CH4, CH5, and CH6. For example, the first and seventh switching elements M1 and M7 may be connected to the first output channel CH1, the third and ninth switching elements M3 and M9 may be connected to the second output channel CH2, the fifth and eleventh switching elements M5 and M11 may be connected to the third output channel CH3, the second and eighth switching elements M2 and M8 may be connected to the fourth output channel CH4, the fourth and tenth switching elements M4 and M10 may be connected to the fifth output channel CH5, and the sixth and twelfth switching elements M6 and M12 may be connected to the sixth output channel CH6.

Turning on and off of the switching elements M1, M2, M3, M4, M5, M6, M7, M8, M9, M10, M11, and M12 may be controlled through the mux control signal MUX1 and MUX2 provided from the timing controller 10 (FIG. 1) and the like. In more detail, the first to sixth switching elements M1, M2, M3, M4, M5, and M6 may be controlled according to the first mux control signal MUX1, and the seventh to the twelfth switching elements M7, M8, M9, M10, M11, and M12 may be controlled according to the second mux control signal MUX2.

The display panel 50 includes a plurality of unit pixels PX1 and PX2 disposed in a matrix form. Each of the unit pixels PX1 and PX2 includes a plurality of pixels PX1, PX2, and PX3.

Each of the pixels PX1, PX2, and PX3 configuring one unit pixel PXU1 and PXU2 includes first and second sub-pixels SP11, SP12, SP21, SP22, SP31 and SP32. Each of the pixels PX1, PX2, and PX3 is driven to display the first image or the second image as described referring to FIG. 3.

The sub-pixels SP11, SP12, SP21, SP22, SP31 and SP32 are connected to corresponding data lines DL1, DL2, DL3, DL4, DL5, DL6, DL7, DL8, DL9, DL10, DL11, and DL12, and the scan lines GL. The switching elements M1, M2, M3, M4, M5, M6, M7, M8, M9, M10, M11, and M12 of the multiplexer 31 are connected to an input end of the data lines DL1, DL2, DL3, DL4, DL5, DL6, DL7, DL8, DL9, DL10, DL11, and DL12, respectively.

At this instance, the sub-pixels SP11, SP12, SP21, SP22, SP31, and SP32 included in the plurality of unit pixels PXU1 and PXU2 may be connected to one output channel CH1, CH2, CH3, CH4, CH5, and CH6 through the switching elements M1, M2, M3, M4, M5, M6, M7, M8, M9, M10, M11, and M12. For example, the first sub-pixels SP11 configuring the first pixel PX1 of the unit pixels PXU1 and PXU2 may be connected to the first output channel CH1 through the first and seventh switching elements M1 and M7, and the second sub-pixels SP12 thereof may be connected to the fourth output channel CH4 through the second and eighth switching elements M2 and M8. The first sub-pixels SP21 configuring the second pixel PX2 of the unit pixels PXU1 and PXU2 may be connected to the second output channel CH2 through the third and ninth switching elements M3 and M9, and the second sub-pixels SP22 thereof may be connected to the fifth output channel CH5 through the fourth and tenth switching elements M4 and M10. The first sub-pixels SP31 configuring the third pixel PX3 of the unit pixels PXU1 and PXU2 may be connected to the third output channel CH3 through the fifth and eleventh switching elements M5 and M11, and the second sub-pixels SP32 thereof may be connected to the sixth output channel CH6 through the sixth and twelfth switching elements M6 and M12.

When the switching elements M1, M2, M3, M4, M5, M6, M7, M8, M9, M10, M11, and M12 are turned on in response to the mux control signal MUX1 and MUX2, a data voltage may be applied to the data lines DL1, DL2, DL3, DL4, DL5, DL6, DL7, DL8, DL9, DL10, DL11, and DL12 connected to the corresponding switching elements M1, M2, M3, M4, M5, M6, M7, M8, M9, M10, M11, and M12. In more detail, when the first to sixth switching elements M1, M2, M3, M4, M5, and M6 are turned on by the first mux control signal MUX1, a data voltage may be applied to the pixels PX1, PX2, and PX3 of the first unit pixel PXU1 connected to the first to sixth data lines DL1, DL2, DL3, DL4, DL5, and DL6. In addition, when the seventh to twelfth switching elements M7, M8, M9, M10, M11, and M12 are turned on by the second mux control signal MUX2, a data voltage may be applied to the pixels PX1, PX2, and PX3 of the second unit pixel PXU2 connected to the seventh to twelfth data lines DL7, DL8, DL9, DL10, DL11, and DL12.

In an embodiment, some of the output buffers 341, 342, 343, 344, 345, and 346 may output a data voltage corresponding to the first image in synchronization with the mux control signal MUX1 and MUX2 in a turn-on level, and the remaining other of the output buffers 341, 342, 343, 344, 345, and 346 may output a data voltage corresponding to the second image in synchronization with the mux control signal MUX1 and MUX2 in a turn-on level. For example, a first group output buffers, that are, the first to third output buffers 341, 342, and 343 may output a data voltage corresponding to the first image in synchronization with the mux control signal MUX1 and MUX2, and a second group output buffers, that are, the fourth to sixth output buffers 344, 345, and 346 may output a data voltage corresponding to the second image in synchronization with the mux control signal MUX1 and MUX2.

If the first image to be displayed in the first sub-pixels SP11, SP21 and SP31 does not exist in a certain frame (for example, the pixels PX1, PX2 and PX3 operate in the second mode in the corresponding frame), the output buffers 341, 342 and 343 may be controlled to output a predetermined dummy data voltage in synchronization with the mux control signal MUX1 and MUX2 in the corresponding frame. On contrary, if the second image to be displayed in the second sub-pixels SP12, SP22 and SP32 does not exist in a certain frame (for example, the pixels PX1, PX2 and PX3 operate in the first mode in the corresponding frame), the fourth to sixth output buffers 344, 345 and 346 may be controlled to output a predetermined dummy data voltage in synchronization with the mux control signal MUX1 and MUX2 in the corresponding frame.

In comparison with the embodiment of FIG. 5, in the embodiment of FIG. 7, one output buffer 341, 342, 343, 344, 345, and 346 may be configured to output a data voltage corresponding to only one image (the first image or the second image) according to the modes. In such an embodiment, a gray scale change between the data voltages output in consecutive horizontal periods is smaller than that of the embodiment of FIG. 5. Therefore, a transition delay between the output data voltages may be minimized, and image quality deterioration may be prevented.

In the embodiment described above, the output channels CH1, CH2, CH3, CH4, CH5, and CH6 of the data driver 30 and the sub-pixels SP11, SP12, SP21, SP22, SP31, and SP32 configuring one unit pixel PXU1 and PXU2 have a connection relationship of 1:1. That is, one output channel CH1, CH2, CH3, CH4, CH5, and CH6 is connected to the sub-pixel SP11, SP12, SP21, SP22, SP31, and SP32 configuring one unit pixel PXU1 and PXU2 in a connection relationship of 1:1, and is connected to the plurality of unit pixels PXU1 and PXU2 in a 1:n relationship through the multiplexer 31.

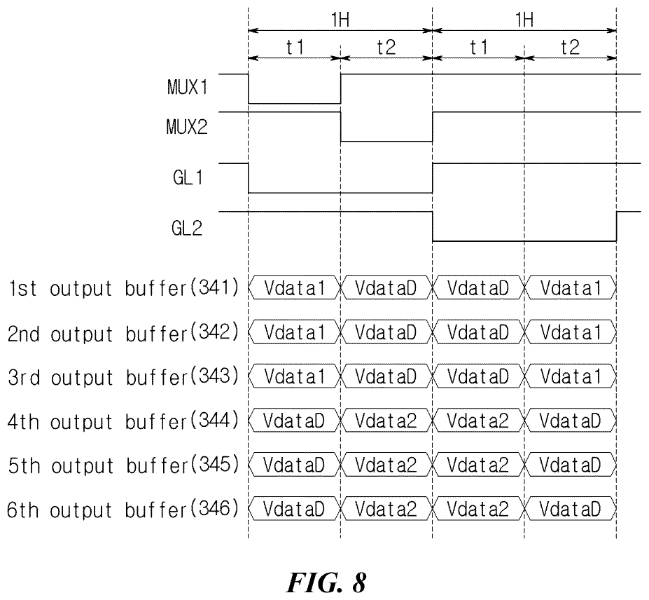

FIG. 8 is a waveform diagram of control and driving signals applied to the display device of FIG. 7. In FIG. 8, an example, in which during one illustrated frame, the first unit pixel PXU1 in the first pixel row operates in the first mode, the first unit pixel PXU1 in the second pixel row operates in the second mode, the first unit pixel PXU1 in the second pixel row operates in the second mode, and the second unit pixel PXU2 in the second pixel row operates in the first mode, is illustrated.

Referring to FIGS. 7 and 8 together, during one frame, a gate signal in a turn-on level is sequentially applied to the scan lines GL1 and GL2. At this instance, each of the gate signals may be applied in a turn-on level during the one horizontal period 1H. The pixels PX1, PX2, and PX3 of the pixel row to which the gate signals in a turn-on level is applied may receive a data voltage through the data lines DL1, DL2, DL3, DL4, DL5, DL6, DL7, DL8, DL9, DL10, DL11, and DL12.

Each of the output buffers 341, 342, 343, 344, 345, and 346 may output a data voltage sequentially with respect to each of the unit pixels PXU1 and PXU2 by timing-dividing the one horizontal period 1H. For example, during a first period t1 of the one horizontal period 1H, the first group output buffers 341, 342, and 343 may output a data voltage of the first sub-pixels SP11, SP21, and SP31 of the first unit pixel PXU1, and the second group output buffers 344, 345, and 346 may output a data voltage of the second sub-pixels SP12, SP22, and SP32 of the first unit pixel PXU1. In addition, during the second period t1 of the one horizontal period 1H, the first group output buffers 341, 342, and 343 may output a data voltage of the first sub-pixels SP11, SP21, and SP31 of the second unit pixel PXU2, and the second group output buffers 344, 345, and 346 may output a data voltage of the second sub-pixels SP12, SP22, and SP 32 of the second unit pixel PXU2.

During the one horizontal period 1H, the timing controller 10 (FIG. 1) provides the mux control signal MUX1 and MUX2 so that the switching elements M1, M2, M3, M4, M5, M6, M7, M8, M9, M10, M11, and M12 of the multiplexer 31 can be turned on sequentially.

In an embodiment, the pixels PX1, PX2, and PX3 of the first unit pixel PXU1 in the first pixel row may operate in the first mode, and the pixels PX1, PX2, and PX3 of the second unit pixel PXU2 in the first pixel row may operate in the second mode. During the first period t1 of the first one horizontal period, the first mux control signal MUX1 in a turn-on level is applied to the multiplexer 31. Then, the first to sixth switching elements M1, M2, M3, M4, M5, and M6 are turned on, a data voltage Vdata1 of the first image output from the first group output buffers 341, 342, and 343 may be applied to each of the first sub-pixels SP11, SP21, and SP31 of the first unit pixel PXU1, and a dummy data voltage VdataD output from the second group output buffers 344, 345, and 346 may be applied to each of the first sub-pixels SP11, SP21, and SP31 of the first unit pixel PXU1.

During the second period t2, the second mux control signal MUX2 in a turn-on level is applied to the multiplexer 31. Then, the seventh to twelfth switching elements M7, M8, M9, M10, M11, and M12 are turned on, a dummy data voltage VdataD output from the first group output buffers 341, 342, and 343 may be applied to each of the first sub-pixels SP11, SP21, and SP31 of the second unit pixel PXU2, and a data voltage Vdata2 of the second image output from the second group output buffers 344, 345, and 346 is applied to each of the second sub-pixels SP12, SP22, and SP32 of the second unit pixel PXU2.

In an embodiment, the pixels PX1, PX2, and PX3 of the first unit pixel PXU1 in the second pixel row may operate in the second mode, and the pixels PX1, PX2, and PX3 of the second unit pixel PXU2 in the second pixel row may operate in the first mode. During the first period t1 of the second one horizontal period, the first mux control signal MUX1 in a turn-on level is applied to the multiplexer 31. Then, the first to sixth switching elements M1, M2, M3, M4, M5, and M6 are turned on, a dummy data voltage VdataD output from the first group output buffers 341, 342, and 343 may be applied to each of the first sub-pixels SP11, SP21, and SP31 of the second unit pixel PXU2, a data voltage Vdata2 of the second image output from the second group output buffers 344, 345, and 346 may be applied to each of the second sub-pixels SP12, SP22, and SP32 of the second unit pixel PXU2.

During the second period t2, the second mux control signal MUX2 in a turn-on level is applied to the multiplexer 31. Then, the seventh to twelfth switching elements M7, M8, M9, M10, M11, and M12 are turned on, a data voltage Vdata1 of the first image output from the first group output buffers 341, 342, and 343 may be applied to each of the first sub-pixels SP11, SP21, and SP31 of the second unit pixel PXU2, and a dummy data voltage VdataD output from the second group output buffers 344, 345, and 346 may be applied to each of the second sub-pixels SP12, SP22, and SP32 of the second unit pixel PXU2.

In such a manner, by allowing the image data in the first mode or the second mode to be selectively applied with respect to each of the unit pixels PXU1 and PXU2 disposed in directions of the pixel row and pixel column, the size, and the shape of the first region A1 (FIG. 2) in which the first image is displayed and the second region A2 (FIG. 2) in which the second image is displayed in the display panel 50 may be freely changed.

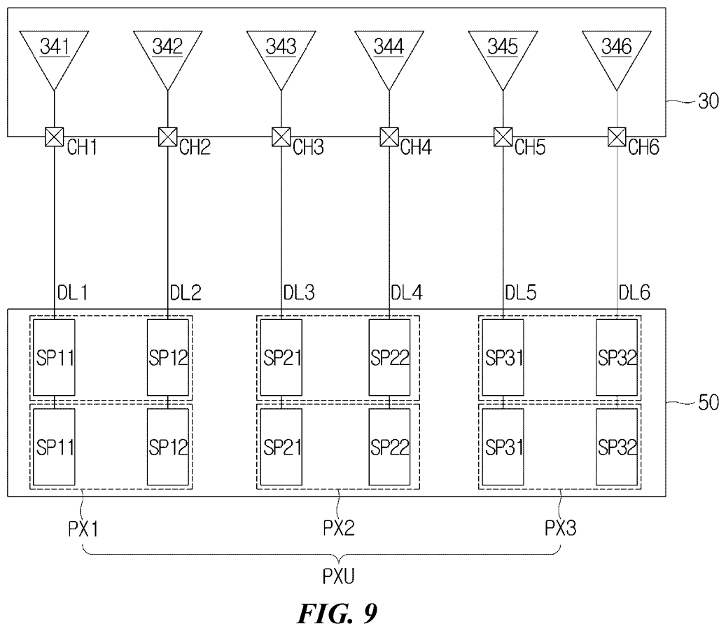

FIG. 9 is a diagram illustrating a connection relationship between a pixel and a data driver according to a third embodiment.

Referring to FIG. 9, the data driver 30 may include a plurality of output channels CH1, CH2, CH3, CH4, CH5, and CH6 connected to a plurality of output buffers 341, 342, 343, 344, 345, and 346, respectively. Each of the output channels CH1, CH2, CH3, CH4, CH5, and CH6 may output a data voltage applied from the connected output buffers 341, 342, 343, 344, 345, and 346.

Each of the output channels CH1, CH2, CH3, CH4, CH5, and CH6 may be connected to the pixels PX1, PX2, and PX3 through the multiplexer 31. For example, the first output channel CH1 may be connected to the first sub-pixel SP11 of the first pixel PX1, the second output channel CH2 may be connected to the second sub-pixel PX12 of the first pixel PX1, the third output channel CH3 may be connected to the first sub-pixel SP21 of the second pixel PX2, the fourth output channel CH4 may be connected the second sub-pixel PX22 of the second pixel PX2, the fifth output channel CH5 may be connected the first sub-pixel SP31 of the third pixel PX3, and the sixth output channel CH6 may be connected to the second sub-pixel SP32 of the third pixel PX3.

The display panel 50 includes a plurality of pixels PX1, PX2, and PX3 disposed in a matrix form. Each of the pixels PX1, PX2, and PX3 includes a plurality of first and second sub-pixels SP11, SP12, SP21, SP22, SP31, and SP32. The sub-pixels SP11, SP12, SP21, SP22, SP31, and SP32 of the pixels PX1, PX2, and PX3 are driven to display the first image or the second image, as described referring to FIG. 3.

The sub-pixels SP11, SP12, SP21, SP22, SP31 and SP32 are connected to corresponding data lines DL1, DL2, DL3, DL4, DL5, and DL6, and scan lines GL. The output channels CH1, CH2, CH3, CH4, CH5, and CH6 are connected to an input end of the data lines DL1, DL2, DL3, DL4, DL5, and DL6, respectively.

In an embodiment, some of the output buffers 341, 342, 343, 344, 345, and 346 may output a data voltage corresponding to the first image, and the remaining other of the output buffers 341, 342, 343, 344, 345, and 346 may output a data voltage corresponding to the second image. For example, the first group output buffers, that are, the first to third output buffers 341, 342, and 343 may output a data voltage corresponding to the first image, and the second group output buffers, that are, the fourth to sixth output buffers 344, 345, and 346 may output a data voltage corresponding to the second image.

If the first image to be displayed in the first sub-pixels SP11, SP21 and SP31 does not exist in a certain frame (for example, the pixels PX1, PX2 and PX3 operate in the second mode in the corresponding frame), the first to third output buffers 341, 342 and 343 may be controlled to output a predetermined dummy data voltage in the corresponding frame. On contrary, if the second image to be displayed in the second sub-pixels SP12, SP22 and SP32 does not exist in a certain frame (for example, the pixels PX1, PX2 and PX3 operate in the first mode in the corresponding frame), the fourth to sixth output buffers 344, 345 and 346 may be controlled to output a predetermined dummy data voltage in the corresponding frame.

In the embodiment described above, the output channels CH1, CH2, CH3, CH4, CH5, and CH6 of the data driver 30 and the sub-pixels SP11, SP12, SP21, SP22, SP31, and SP32 configuring one unit pixel PXU1 and PXU2 have a connection relationship of 1:1. That is, one output channel CH1, CH2, CH3, CH4, CH5, and CH6 is connected to the sub-pixel SP11, SP12, SP21, SP22, SP31, and SP32 configuring one unit pixel PXU1 and PXU2 in a connection relationship of 1:1.

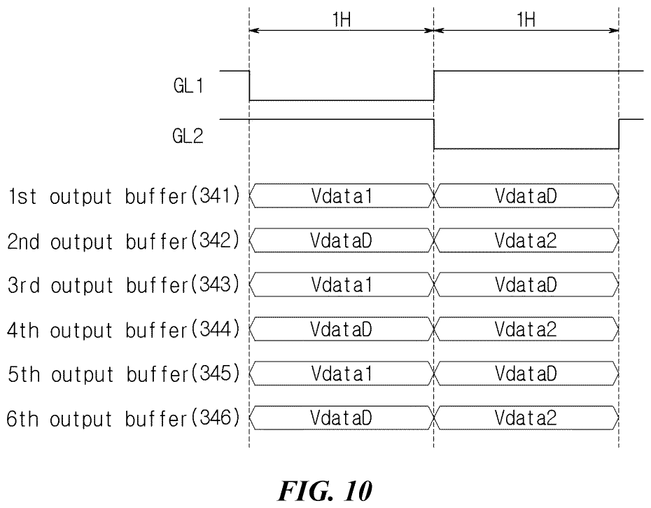

FIG. 10 is a waveform diagram of control and driving signals applied to the display device of FIG. 9. In FIG. 10, an example, in which during one illustrated frame, the pixels PX1, PX2, and PX3 in the first pixel row operate in the first mode, and the pixels PX1, PX2, and PX3 in the second pixel row operate in the second mode, is illustrated.

Referring to FIGS. 9 and 10 together, during one frame, a gate signal in a turn-on level is sequentially applied to the scan lines GL1 and GL2. At this instance, each of the gate signals may be applied in a turn-on level during the one horizontal period 1H. The pixels PX1, PX2, and PX3 of the pixel row to which the gate signals in a turn-on level is applied may receive a data voltage through the data lines DL1, DL2, DL3, DL4, DL5, and DL6.

The pixels PX1, PX2, and PX3 in the first pixel row may operate in the first mode. During the first one horizontal period 1H, each of the output buffers 341, 342, 343, 344, 345, and 346 may output a data voltage with respect to the sub-pixels SP11, SP12, SP21, SP22, SP31, and SP32 configuring one pixel PX1, PX2, and PX3. For example, during the first one horizontal period 1H, the first group output buffer 341, 342, and 343 may output the first data voltage Vdata1 to the first sub-pixels SP11, SP21, and SP31, and the second group output buffer 344, 345, and 346 may output the dummy data voltage VdataD to the second sub-pixels SP12, SP22, and SP32.

The pixels PX1, PX2, and PX3 in the second pixel row may operate in the second mode. During the second one horizontal period 1H, each of the output buffers 341, 342, 343, 344, 345, and 346 may output a data voltage with respect to the sub-pixels SP11, SP12, SP21, SP22, SP31, and SP32 configuring one pixel PX1, PX2, and PX3. For example, during the first one horizontal period 1H, the first group output buffer 341, 342, and 343 may output the dummy data voltage VdataD to the first sub-pixels SP11, SP21, and SP31, and the second group output buffer 344, 345, and 346 may output the data voltage of the second image Vdata2 to the second sub-pixels SP12, SP22, and SP32.

In such a manner, by allowing the image data in the first mode or the second mode to be selectively applied with respect to the pixel rows, the size, and the shape of the first region A1 (FIG. 2) in which the first image is displayed and the second region A2 (FIG. 2) in which the second image is displayed in the display panel 50 may be freely changed.

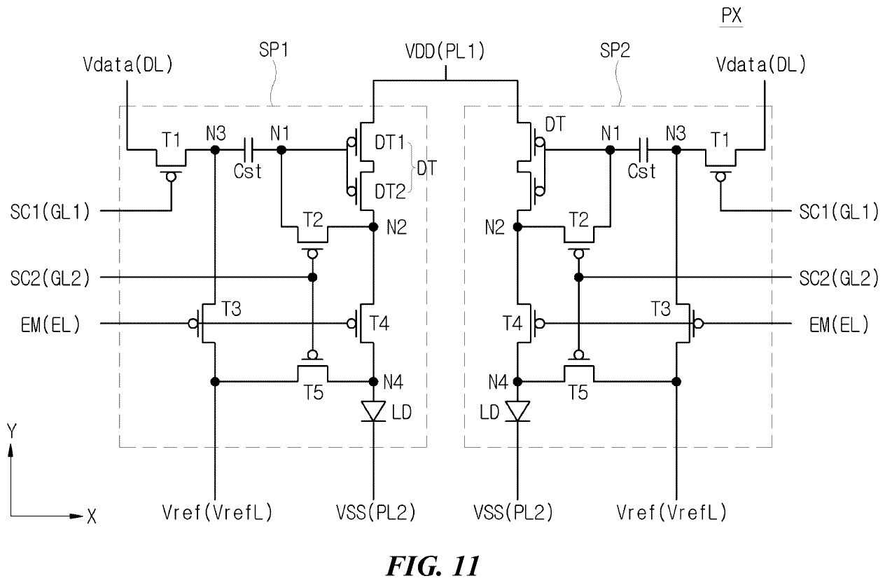

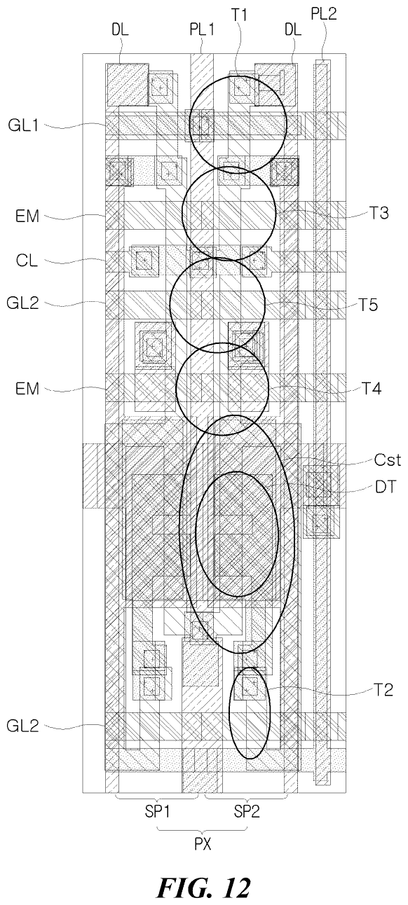

FIG. 11 is a circuit diagram of a pixel according to an embodiment. FIG. 12 is a plan view illustrating a layout of a pixel illustrated in FIG. 11.

Referring to FIGS. 11 and 12 together, the display panel 50 includes, a first scan line SC1, a second scan line SC2 and a light emission line EL extending in a row direction, and a high potential driving voltage line PL1, a low potential driving voltage line PL2, a data line DL, and a reference voltage line VrefL extending in a column direction generally perpendicular to the row direction. One sub-pixel SP1 and SP2 may be formed in a region in which the first scan line SC1, the second scan line SC2, and the light emission line EL, and the high potential driving voltage line PL1, the low potential driving voltage line PL2, the data line DL, and the reference voltage line VrefL intersect each other.

Two sub-pixels PS1 and SP2 adjacent to each other in the row direction may configure one pixel PX. The sub-pixels SP1 and SP2 configuring one pixel PX may be configured with the same or different circuits. When the sub-pixels SP1 and SP2 configuring one pixel PX is configured with the same circuit, the sub-pixels SP1 and SP2 may have a layout mirrored with each other based on the column direction. In more detail, the adjacent two sub-pixels SP1 and SP2 forming one pixel PX may have a layout mirrored with each other based on the high potential driving voltage line PL1. However, the present embodiment is not limited thereto.

The first scan line SC1, the second scan line SC2, and the light emission line EL traverse the sub-pixels SP1 and SP2 and extend in the row direction. The high potential driving voltage line PL1, the low potential driving voltage line PL2, the data line DL, and the reference voltage line VrefL extend in the column direction between two adjacent sub-pixels SP1 and SP2. For example, the high potential driving voltage line PL1 extends in the column direction between two adjacent sub-pixels SP1 and SP2, the data line DL may extend in the column direction on one side of each sub-pixel SP1 and SP2, and may extend in the column direction between two adjacent pixels PX. The reference voltage line VrefL and the low potential driving voltage line PL2 may extend in the column direction on one side of at least some sub-pixel SP1 and SP2 among the sub-pixels SP1 and SP2 of the plurality of pixels PX.

In an embodiment, two or more adjacent sub-pixels SP1 and SP2 may share at least one among the high potential driving voltage line PL1, the low potential driving voltage line PL2, the data line DL, and the reference voltage line VrefL. For example, two sub-pixels SP1 and SP2 included in one pixel PX may share one high potential driving voltage line PL1. In addition, for example, two or more pixels PX may share the low potential driving voltage line PL2, and/or the reference voltage line VrefL. At this instance, so as to connect the reference voltage line VrefL extending in the column direction to each sub-pixel SP1 and SP2, a connection line CL extending in the column direction may be formed by passing through the sub-pixels SP1 and SP2. However, the present embodiment is not limited thereto.

Hereinafter, a configuration of the sub-pixels SP1 and SP2 will be described based on the first sub-pixel SP1.

The first sub-pixel SP1 according to an embodiment may include a driving transistor DT, a light emitting diode LD connected to the driving transistor DT, and a control circuit configured to control an amount of a driving current to be applied to the light emitting diode LD through the driving transistor DT. For example, the control circuit may include first to fifth transistors T1 to T5, and a capacitor Cst. In such an embodiment, one pixel PX has a 12T2C structure.

A first electrode of the driving transistor DT is configured to receive the high potential driving voltage VDD (connected to the high potential driving voltage line PL1), and a second electrode thereof is connected to a second node N2. A gate electrode of the driving transistor DT is connected to the second node N2. The driving transistor DT may control an amount of a current of a driving current which is turned on in response to a voltage applied to a first node N1 and flows to the light emitting diode LD.

In an embodiment, the driving transistor DT may be configured with two auxiliary driving transistors DT1 and DT2 connected in series, as illustrated. At this instance, a first auxiliary driving transistor DT1 is connected between the high potential driving voltage VDD and a second auxiliary driving transistor DT2, and the second auxiliary driving transistor DT2 may be connected between the first auxiliary driving transistor DT1 and the first node N1. A gate electrode of the first auxiliary driving transistor DT1 and the second auxiliary driving transistor DT2 is connected to the first node N1. However, the embodiment is not limited thereto.

A first electrode of the first transistor T1 is connected to a data line DL, and a second electrode thereof is indirectly connected to a gate electrode of the driving transistor DT through a third node N3. A gate electrode of the first transistor T1 is connected to a first scan line GL1 and may receive a first scan signal SC1. The first transistor T1 may be turned on in response to the first scan signal SC1 applied to the first scan line GL1, and may transmit a data voltage Vdata applied to the data line DL to the third node N3. Such a first transistor T1 may be referred to as a switching transistor.

When the pixel PX operates in the first mode in a certain frame, the first transistor T1 of the first sub-pixel SP1 may receive a data voltage Vdata of the first image (FIG. 2) applied to the data line DL. When the pixel PX operates in the second mode in a certain frame, the first transistor T1 may receive a dummy data voltage through the data line DL.

A first electrode of the second transistor T2 may be connected to the gate electrode of the driving transistor DT through the first node N1, and a second electrode thereof may be connected to the second electrode of the driving transistor DT through the second node N2. A gate electrode of the second transistor T2 may be connected to a second scan line GL2, and may receive a second scan signal SC2. The second transistor T2 is turned on in response to the second scan signal SC2 applied to the second scan line GL2, and connects the gate electrode and the second electrode of the driving transistor DT to each other.

A first electrode of a third transistor T3 is configured to receive the reference voltage Vref (connected to the reference voltage line VrefL), and a second electrode thereof is connected to the third node N3. A gate electrode of the third transistor T3 is connected to the light emission line EL, and may receive a light emission signal EM. The third transistor T3 is turned on in response to the light emission signal EM applied to the light emission line EL, and may receive the reference voltage Vref to the third node N3. Such a third transistor T3 may be referred to as an initialization transistor.

A first electrode of a fourth transistor T4 is connected to the driving transistor DT through the second node N2, and a second electrode thereof is connected to the light emitting diode LD through a fourth node N4. A gate electrode of the fourth transistor T4 is connected to the light emission line EL, and may receive the light emission signal EM. The fourth transistor T4 may be turned on in response to the light emission signal EM applied to the light emission line EL, and may connect the driving transistor DT and the light emitting diode LD to each other. When the fourth transistor T4 is turned on, a current path is formed between the high potential driving voltage VDD and the low potential driving voltage VSS, and a driving current flows to the light emitting diode LD, thereby the light emitting diode LD may emit light. Such a fourth transistor T4 may be referred to as a light emitting transistor.

A first electrode of a fifth transistor T5 is configured to receive the reference voltage Vref (connected to the reference voltage line VrefL), and a second electrode thereof is connected to an anode electrode of the light emitting diode LD through the fourth node N4. A gate electrode of the fifth transistor T5 is connected to the second scan line GL2, and may receive the second scan signal SC2. The fifth transistor T5 is turned on in response to the second scan signal SC2 applied to the second scan line GL2, and may transmit the reference voltage Vref to the anode electrode of the light emitting diode LD. Such a fifth transistor T5 may be referred to as an anode initialization transistor.

The capacitor Cst is connected between the first node N1 and the third node N3. The capacitor Cst may store a voltage corresponding to a voltage difference between the first node N1 and the third node N3.

The light emitting diode LD has the anode electrode connected to the fourth node N4, and a cathode electrode connected to the low potential driving voltage VSS. When the driving transistor DT and the fourth transistor T4 are turned on, a current path is formed between the high potential driving voltage VDD and the low potential driving voltage VSS, and the driving current may flow to the light emitting diode LD. The light emitting diode LD may emit light at luminance corresponding to a current amount of the driving current applied thereto.

In the embodiment illustrated in FIG. 7, the pixel PX may be configured as a low temperature poly-silicon (LTPS) thin film transistor. The LTPS thin film transistor includes a gate electrode, a source electrode, and a drain electrode. The LTPS thin film transistor has an active layer formed of poly silicon. Such an LTPS thin film transistor may be configured as a P-type thin film transistor. The LTPS thin film transistor has a high electron mobility, and therefore, has a fast driving characteristic.

In another embodiment, the pixel PX may be configured as an oxide semiconductor thin film transistor, or may be configured as a hybrid type including the LTPS thin film transistor and an oxide semiconductor thin film transistor. The oxide semiconductor thin film transistor includes a gate electrode, a source electrode, and a drain electrode. The oxide semiconductor thin film transistor includes an active layer formed of an oxide semiconductor. Here, the oxide semiconductor may be set as an amorphous or a crystalline oxide semiconductor. The oxide semiconductor thin film transistor may be configured as an n-type transistor. The oxide semiconductor thin film transistor may be formed through a low temperature process and has a lower charge mobility than that of the LTPS thin film transistor. Such an oxide semiconductor thin film transistor has an excellent off current characteristic.

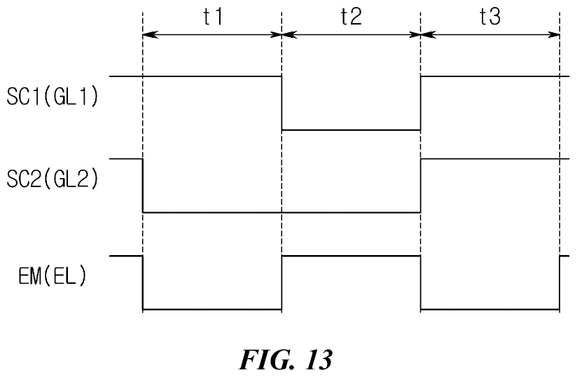

FIG. 13 is a diagram illustrating a method for driving a pixel illustrated in FIG. 11.

Referring to FIGS. 13 and 11 together, one frame may include an initialization period t1, a sampling and programming period t2, and a light emitting period t3.

In the initialization period t2, the light emission signal EM and the second scan signal SC2 in a turn-on level (for example, a low level) are applied, and the second to fifth transistors T2, T3, T4, and T5 are turned on.

Then, through the third transistor T3 which is turned on, a reference voltage Vref is applied to the third node N3, and the third node N3 may be initialized to have the reference voltage Vref.

In addition, through the fifth, fourth, and second transistors T2, T4, and T5 which are turned on, a reference voltage Vref is applied to the fourth node N4, the second node N2, and the first node N1, and the fourth node N4, the second node N2, and the first node N1 may be initialized to have the reference voltage Vref. At this instance, the reference voltage Vref is set to be lower than a threshold voltage of the light emitting diode LD, thereby the light emitting diode LD may not emit light.

During the initialization period t1, the high potential driving voltage line PL1, the driving transistor DT, the fourth transistor T4, the fifth switching transistor T5, and the reference voltage line VrefL are substantially connected to form a current path, and each of the first node N1 and the third node N3 is connected to the corresponding current path through the first switching transistor T1 and the second switching transistor T2. Therefore, the first node N1 and the third node N3 are converged identically to an arbitrary voltage between the high potential driving voltage VDD and the reference voltage Vref, and the capacitor Cst gets into a state in which both electrodes have no voltage difference.

In the sampling and programming period t2, the light emission signal EM is changed over to a turn-off level (for example, a high level), and the third transistor T3 and the fourth transistor T4 are turned off. Moreover, in the sampling and programming period t2, the first scan signal SC1 is changed over to a turn-on level, and the first transistor T1 may be turned on.

Then, through the first transistor which is turned on, a data voltage Vdata may be applied to the first electrode of the storage capacitor Cst, that is, the third node N3. In addition, because the second transistor T2 is in a turn-on state, the driving transistor DT gets into a diode-connected state, as the second electrode and the gate electrode of the driving transistor DT are short-circuited.

In the sampling and programming period t2, the driving transistor DT gets into a turn-on state, and a current flows between the source and the drain of the driving transistor DT (that is, between the first electrode and the second electrode of the driving transistor DT). At this instance, because the driving transistor DT is in a diode-connected state, a voltage of the gate electrode of the driving transistor DT, that is, a voltage of the first node N1 may gradually rise. At this instance, a voltage of the first node N1 may rise until reaching a voltage corresponding to a voltage difference VDD−Vth between the high potential voltage VDD and a threshold voltage Vth of the driving transistor DT.

A voltage VDD−Vth−Vdata corresponding to a voltage difference between the first node N1 and the third node N3 is stored in the capacitor Cst.

Meanwhile, in the sampling and programming period t2, the anode electrode of the light emitting diode LD may maintain a reference voltage Vref state through the fifth transistor T5 in a turn-on state.

In the light emitting period t3, the first scan signal SC1 and the second scan signal SC2 are changed over to a turn-off level, and the light emission signal EM is changed over to a turn-on level, thereby the third transistor T3 and the fourth transistor T4 may be turned on.

Then, a reference voltage Vref may be applied to the third node N3 through the third transistor T3 which is turned on. Next, a voltage of the third node N3 may change into a reference voltage Vref from a voltage of the previous period, that is, the data voltage Vdata. In correspondence with the change amount of the voltage of the third node N3, a voltage VDD−Vth−Vdata+Vref of the first node may be changed through the storage capacitor Cst.

In addition, through the fourth transistor T4 which is turned on, a current path starting from the high potential driving voltage VDD, passing the driving transistor DT, and reaching the light emitting diode LD is formed. As a result, a driving current having a magnitude corresponding to a voltage programmed into the driving transistor DT is provided to the light emitting diode LD, thereby allowing the light emitting diode LD to emit light at corresponding luminance.

Here, the high potential driving voltage VDD is applied to the first electrode, which is the source electrode of the driving transistor DT, and the first node N1 which is the gate electrode has a changed voltage VDD−Vth−Vdata+Vref, and therefore, the source-gate voltage Vsg of the driving transistor DT becomes VDD−(VDD−Vth−Vdata+Vref)=(Vdata+Vth−Vref). That is, the voltage programmed into the driving transistor DT is a voltage obtained by compensating for the data voltage Vdata by as much as the threshold voltage Vth, thereby the deterioration of the driving transistor DT may be compensated.

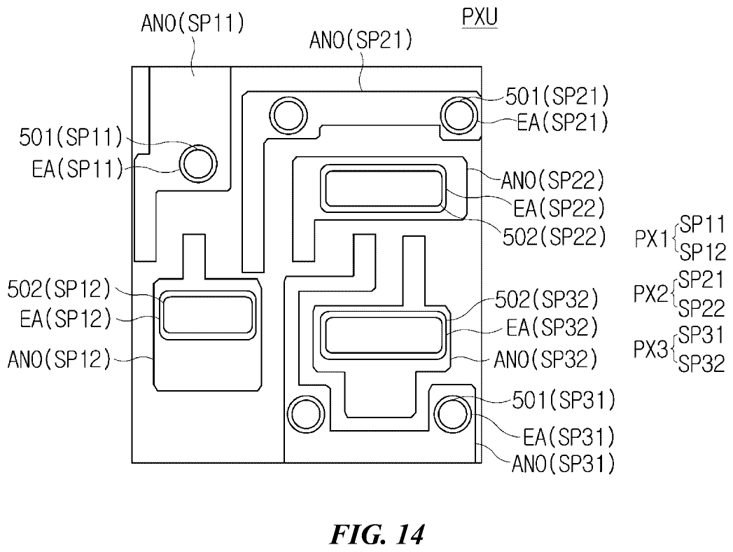

FIG. 14 is a plan view of the unit pixel according to an embodiment.

FIG. 14 shows a plan view of an upper portion of the unit pixel PXU, in case three pixels PX1, PX2, and PX3 are disposed in the unit pixel PXU, and each of the pixels PX1, PX2, and PX3 includes two sub-pixels SP11, SP12, SP21, SP22, SP31, and SP32.

Each of the pixels PX1, PX2, and PX3 includes the light emitting diode LD (FIG. 11). Therefore, each of the sub-pixels SP11, SP12, SP21, SP22, SP31, and SP32 includes an anode electrode ANO configuring the light emitting diode LD. The anode electrode ANO of the sub-pixels SP11, SP12, SP21, SP22, SP31, and SP32 may have the same or different shape and size. As illustrated, the anode electrode ANO may have various shapes including not only a polygonal, circular or oval shape, but also a shape of which at least one portion is bent.

Each of the sub-pixels SP11, SP12, SP21, SP22, SP31, and SP32 has a light emitting region EA defined by each of the light emitting diodes LD. The light emitting region EA may be defined as a region in which the anode electrode ANO is exposed to an upper portion without being covered by an upper insulation layer (for example, a bank which will be described below). A size and a shape of the light emitting region EA of each of the sub-pixels SP11, SP12, SP21, SP22, SP31, and SP32 may be the same or different from one another. In an embodiment, the light emitting region EA of the first sub-pixels SP11, SP21, and SP31 may be generally circular, and the light emitting region EA of the second sub-pixels SP12, SP22, and SP32 may be generally quadrangular, but are not limited thereto.

In addition, a quantity of the light emitting region EA provided in one sub-pixel SP11, SP12, SP21, SP22, SP31, and SP32 may be one or more, and may be the same or different with respect to the sub-pixels SP11, SP12, SP21, SP22, SP31, and SP32. In an embodiment, one light emitting region EA may be formed in some of the first sub-pixels SP11, SP21, and SP31, and a plurality of light emitting regions EA may be formed in the remaining other. In an embodiment, one light emitting region EA may be formed in each of the second sub-pixels SP12, SP22, and SP32. However, the quantity of the light emitting region EA is not limited thereto.

In an embodiment, the first, second, and third pixels PX1, PX2, and PX3 may be red, green, and blue pixel, respectively. Accordingly, the light emitting diode LD of the sub-pixels SP11 and SP12 of the first pixel PX1 may emit red light, the light emitting diode LD of the sub-pixels SP21 and SP22 of the second pixel PX2 may emit green light, and the light emitting diode LD of the sub-pixels SP31 and SP32 of the third pixel PX3 may emit blue light.

On each of the sub-pixels SP11, SP12, SP21, SP22, SP31, and SP32, a lens member which includes a plurality of lenses 501 and 502 is disposed. The lens member may include a first lens 501 and a second lens 502, each of which provides a different viewing angle. For example, the first lens 501 may be disposed in the light emitting regions EA of the first sub-pixels SP11, SP21, and SP31, and the second lens 502 may be disposed in the light emitting regions EA of the second sub-pixels SP12, SP22, and SP32.

A size and a shape of the first lens 501 or the second lens 502 disposed in each of the light emitting regions EA may be different from each other so as to provide each different viewing angle. For example, the first lens 501 may be a hemispherical lens having a flat lower surface and a spherical upper surface, opposite the lower surface. For example, the second lens 502 may be a semicylindrical lens having a flat lower surface and a cylindrical upper surface, opposite the lower surface. However, the embodiment is not limited thereto.

Through the first lens 501 and the second lens 502 having each different shape, a viewing angle of the display panel 50 may be controlled. In more detail, directions of viewing angle limitation of the first lens 501 and the second lens 502 are different from each other, and a narrow viewing angle and a wide viewing angle may be implemented through above-described selective driving of the sub-pixels SP11, SP12, SP21, SP22, SP31, and SP32.

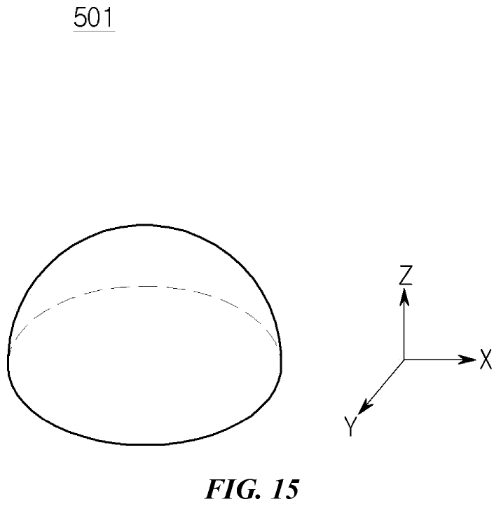

A method for implementing the narrow viewing angle and the wide viewing angle using the lenses 501 and 502 will be described in more detail below with reference to FIGS. 15 to 18.

The quantity of the first lens 501 or the second lens 502 disposed in each of the sub-pixels SP11, SP12, SP21, SP22, SP31, and SP32 may be the same or different according to the quantity of the light emitting region EA.

In an embodiment, one or more first lenses 501 or second lenses 502 may be disposed in one sub-pixel SP11, SP12, SP21, SP22, SP31, and SP32. For example, one first lens 501 or second lens 502 may be disposed in some of the sub-pixels SP11, SP12, SP21, SP22, SP31, and SP32 and two or more first lenses 501 or second lenses 502 may be disposed in the remaining other of the sub-pixels SP11, SP12, SP21, SP22, SP31, and SP32. In an illustrated embodiment, one or more first lenses 501 are disposed in each of the first sub-pixels SP11, SP21, and SP31, and one second lens 502 is disposed in each of the second sub-pixels SP12, SP22, and SP32. However, the present embodiment is not limited thereto.

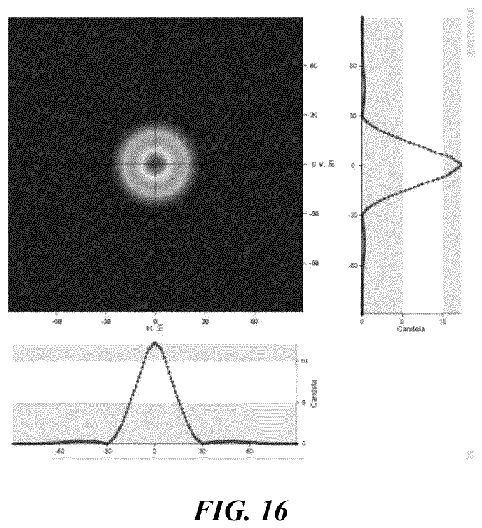

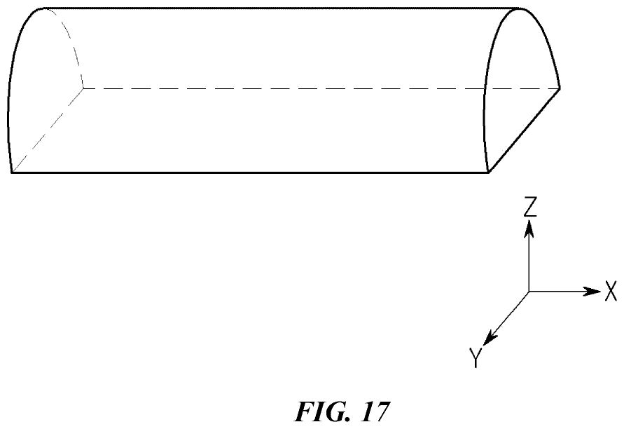

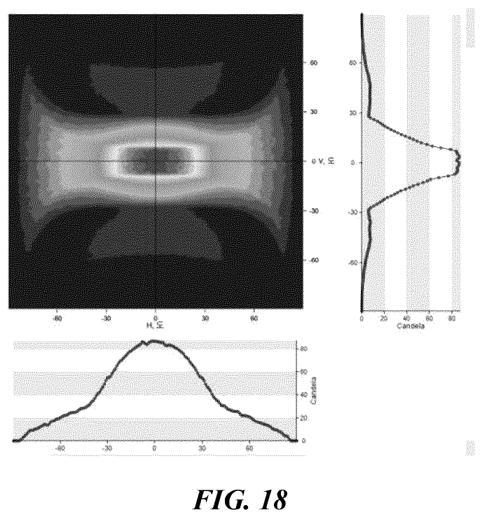

FIG. 15 is a view schematically illustrating the first lens illustrated in FIG. 14. FIG. 16 is a view illustrating a light profile with respect to a viewing angle of the first lens illustrated in FIG. 15. FIG. 17 is a view schematically illustrating the second lens illustrated in FIG. 14. FIG. 18 is a view illustrating a light profile with respect to a viewing angle of the second lens illustrated in FIG. 17.

As illustrated in FIG. 15, the first lens 501 is a hemispherical lens, and has a cross-section having a semicircular shape in X and Y directions. Therefore, the first lens 501 limits a viewing angle in the X and Y directions.

Meanwhile, as illustrated in FIG. 17, the second lens 502 is a semicylindrical lens, and has a cross-section having a rectangular shape in the X direction and a semicircular shape in the Y direction. Therefore, the second lens 502 limits a viewing angle in the Y direction, and does not limit a viewing angle in a longitudinal direction, that is, in the X direction.

As illustrated in FIG. 16, the light emitting regions EA11, EA21, and EA31 (FIG. 14) of the first sub-pixels SP11, SP21, and SP31 (FIG. 14) having the first lens 501 in the hemispherical shape have a narrow viewing angle of about 30 degrees or less vertically and horizontally. Meanwhile, as illustrated in FIG. 18, the light emitting regions EA12, EA22, and EA32 (FIG. 14) of the second sub-pixels SP12, SP22, and SP32 (FIG. 14) having the second lens 502 in the semicylindrical shape have a wide viewing angle of about 60 degrees or more vertically and horizontally.

Therefore, a vertical narrow viewing mode and a horizontal narrow viewing mode (that is, a privacy mode) may be implemented with respect to the first image to be displayed in the first sub-pixels SP11, SP21, and SP31, and a vertical narrow viewing mode and a horizontal wide viewing mode (that is, a share mode) may be implemented with respect to the second image to be displayed in the second sub-pixels SP12, SP22, and SP32.

As described above, the display panel 50 (FIG. 1) has a narrow viewing angle in the vertical direction all the time, and therefore, it is possible to prevent interference in the traveling view caused by an image reflected on a front glass of a vehicle when the display panel is applied in a vehicle.

In addition, the display panel 50 may display the first image having the narrow viewing angle in the horizontal direction in the first region A1 (FIG. 2) operating in the first mode, and may display the second image having the wide viewing angle in the horizontal direction in the second region A2 (FIG. 2) operating in the second mode.

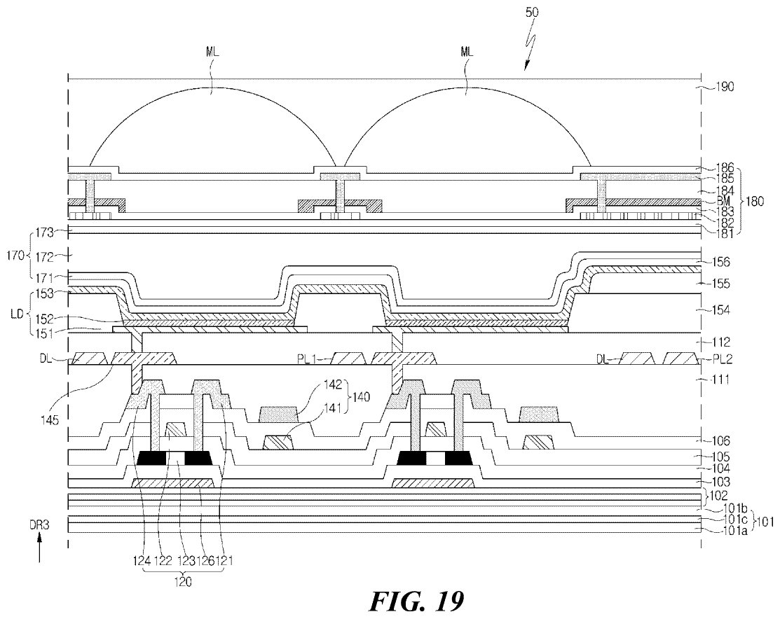

Hereinafter, a lamination form of the pixel in more detail will be described with reference to FIG. 19.

FIG. 19 is a cross-sectional view schematically illustrating the display region of the display panel according to an embodiment. In FIG. 19, a cross-section of two sub-pixels SP disposed adjacent to each other is illustrated. In particular, a cross-section of the first sub-pixels displaying the first mage is illustrated.

Referring to FIG. 19, the display panel 50 may include a substrate 101, a thin film transistor 120, the light emitting diode LD, an encapsulation unit 170, and a touch unit 180, etc. However, the embodiments of the present disclosure are not limited thereto.

The substrate 101 may provide a space in which various components can be disposed in an upper portion thereof. The substrate 101 may correspond to a flat surface shape of the display panel 50 in FIG. 1. In other words, the substrate 101 generally has a quadrangular or circular shape, but is not limited thereto. The substrate 101 may have various shapes such as a polygonal shape, an oval shape, and the like. In an embodiment, the substrate 101 may include at least one notch portion. The substrate 101 may include the display region AA (FIG. 2) and the non-display region NA (FIG. 2) of the display panel 50 substantially identically.

The substrate 101 may include one or more plastic materials such as polyimide and the like, or a glass material. For example, the substrate 101 may be a multi-structured substrate which includes a plurality of substrates including a first substrate 101a, a second substrate 101b, and a third substrate 103c, but the embodiments of the present disclosure are not limited thereto. For example, the substrate 101 may be a single-structured substrate consisting of one layer.

The substrate 101 may be a rigid substrate or a flexible substrate.

A buffer layer 102 may be disposed on the substrate 101. The buffer layer 102 may minimize or delay dispersion of moisture or oxygen permeating the substrate 101. The buffer layer 102 may be formed by alternately laminating silicon nitride SiNₓ and silicon oxide SiOₓ at least once, but is not limited thereto.

In FIG. 19, the buffer layer 102 is illustrated as a multi-structured layer configured with three layers, but a quantity of layers configuring the buffer layer 102 is not limited thereto, and the buffer layer 102 may be formed as a single-structured layer.

A light shielding layer 126 may be disposed on the buffer layer 102. The light shielding layer 126 may prevent transmission of light into a semiconductor layer 123 of the thin film transistor 120. For example, the semiconductor layer 123 may be disposed by overlapping the light shielding layer 126. The light shielding layer 126 may be a single-structured layer or a multi-structured layer formed of one among molybdenum (Mo), aluminum (Al), chrome (Cr), nickel (Ni), neodymium (Nd), and copper (Cu), or an alloy of two or more of the above, but is not limited thereto.

A first insulation layer 103 may be disposed on the light shielding layer 126. The first insulation layer 103 may prevent an electrical short between a component of the thin film transistor 120 and the light shielding layer 126. The first insulation layer 103 may be formed of the same material as the buffer layer 102, but the embodiments of the present disclosure are not limited thereto. For example, the first insulation layer 103 may be formed of an inorganic insulating material such as silicon nitride SiNₓ, silicon oxide SiOₓ, and the like, but is not limited thereto.

The thin film transistor 120 may be disposed on the first insulation layer 103. The thin film transistor 120 may include a source electrode 121, a gate electrode 122, the semiconductor layer 123, and a drain electrode 124.

The semiconductor layer 123 may be disposed on the first insulation layer 103. The semiconductor layer 123 may include a source region, a drain region, and a channel region between the source region and the drain region.

The semiconductor layer 123 may include a metal oxide semiconductor such as Indium-Gallium-Zinc Oxide (IGZO), etc., and a silicon-based semiconductor material such as amorphous silicon or polycrystalline silicon, etc., but the embodiments of the present disclosure are not limited thereto. A polycrystalline silicon layer has higher mobility than an amorphous silicon layer and an oxide semiconductor layer, and thus, may consume less power and have excellent reliability. Therefore, the driving transistor DT (FIG. 13) may be formed as the polycrystalline silicon layer, but is not limited thereto.

A second insulation layer 104 may be disposed on the semiconductor layer 123. The second insulation layer 104 may be formed of the same material as the first insulation layer 103, however the embodiments of the present disclosure are not limited thereto. The second insulation layer 104 may prevent an electrical short between the other component of the thin film transistor 120 and the semiconductor layer 123.

The gate electrode 122 may be disposed on the second insulation layer 104. The gate electrode 122 may be disposed on the second insulation layer 104 to overlap the channel region of the semiconductor layer 123. The gate electrode 122 may be formed in a single-layered structure or a multi-layered structure formed of one among molybdenum (Mo), copper (Cu), titanium (Ti), aluminum (Al), chrome (Cr), gold (Au), nickel (Ni), neodymium (Nd), and or an alloy thereof, but the embodiments of the present disclosure are not limited thereto. The gate electrode 122 may be disposed together with the scan line GL (FIG. 13), but the embodiments of the present disclosure are not limited thereto.

A third insulation layer 105 and a fourth insulation layer 106 may be disposed on the gate electrode 122. The third insulation layer 105 and the fourth insulation layer 106 may be formed of the same material as the first insulation layer 103 or the second insulation layer 104, but the embodiments of the present disclosure are not limited thereto.

The source electrode 121 and the drain electrode 124 may be disposed on the fourth insulation layer 106. The source electrode 121 and the drain electrode 124 may be electrically connected to the semiconductor layer 123 through a contact hole. The source electrode 121 and the drain electrode 124 may be formed of a metal material. For example, the source electrode 121 and the drain electrode 124 may be formed in a single-layered structure or a multi-layered structure formed of one among molybdenum (Mo), aluminum (Al), chrome (Cr), gold (Au), titanium (Ti), nickel (Ni), neodymium (Nd), and copper (Cu), or an alloy thereof, but the embodiments of the present disclosure are not limited thereto.

A storage electrode 140 may be disposed to be spaced apart from the first thin film transistor 120. The storage electrode 140 may include a first storage electrode 141, and a second storage electrode 142.

The first storage electrode 141 may be disposed on the third insulation layer 105. The first storage electrode 141 may be formed of a metal material. For example, the first storage electrode 141 may be a multi-structured layer formed of one among molybdenum (Mo), aluminum (Al), chrome (Cr), gold (Au), titanium (Ti), nickel (Ni), neodymium (Nd), and copper (Cu), or an alloy of two or more of the above, but the embodiments of the present disclosure are not limited thereto. The first storage electrode 141 may be covered by the fourth insulation layer 106.

The second storage electrode 142 may be disposed to overlap the first storage electrode 141 in at least one region, and may be disposed on the fourth insulation layer 106. The second storage electrode 142 may be formed of the same material as the source electrode 121 and the drain electrode 124, but is not limited thereto. Alternatively, the second storage electrode 142 may be formed of the same material as the first storage electrode 141, but is not limited thereto.

A capacitance may be formed with the fourth insulation layer 106 between the first storage electrode 141 and the second storage electrode 142 serving as the dielectric.

The thin film transistor 120 may be a driving transistor DT (FIG. 11), and though not illustrated, the display panel 50 may further include a transistor.

A first protection layer 111 may be disposed on the source electrode 121 and the drain electrode 124.

The first protection layer 111 may planarize an upper portion of the first thin film transistor 120, and protect the first thin film transistor 120. The first protection layer 111 may be formed of an organic material. For example, the first protection layer 111 may be formed of an organic material including an acrylic resin, an epoxy resin, a phenolic resin, a polyamide resin, or a polyimide resin, but is not limited thereto.

A second protection layer 112 may be disposed on the first protection layer 111. The second protection layer 112 may be formed of the same material as the first protection layer 111, but is not limited thereto.

A connection electrode 145 may be disposed between the first protection layer 111 and the second protection layer 112. The connection electrode 145 may electrically connect the thin film transistor 120 and the light emitting diode LD. The connection electrode 145 may be formed of the same material as the source electrode 121 and the drain electrode 124, but is not limited thereto. The connection electrode 145 may be electrically connected to the drain electrode 124 by contacting the drain electrode 124 through a contact hole formed on the first protection layer 111. The connection electrode 145 may be formed in a single-layered structure or a multi-layered structure formed of one among molybdenum (Mo), aluminum (Al), chrome (Cr), gold (Au), titanium (Ti), nickel (Ni), neodymium (Nd), and copper (Cu), or an alloy thereof, but is not limited thereto.

The connection electrode 145 may be disposed together with the high potential driving voltage line PL1 and the data line DL. For example, the high potential driving voltage line PL1 and the data line DL may be formed of the same material on the same layer as the connection electrode 145, but are not limited thereto. The connection electrode 145 may be further formed on the same layer as the low potential driving voltage line PL2 and the reference voltage line VrefL, which are not illustrated.

The light emitting diode LD may be formed on the second protection layer 112. The light emitting diode LD may include an anode electrode 151, an organic layer 152, and a cathode electrode 153.

The anode electrode 151 may be disposed on the second protection layer 112. The anode electrode 151 may be electrically connected to the first thin film transistor 120 through the contact hole formed on the first protection layer 111 and the second protection layer 112. The anode electrode 151 may be a reflective electrode which reflects light, but the embodiments of the present disclosure are not limited thereto. The anode electrode 151 may include a metal material having a high reflectance such as an APC alloy (Ag/Pd/Cu), a deposition structure (Ti/Al/Ti) of aluminum (Al) and titanium (Ti), and a deposition structure (ITO/Al/ITO) of aluminum (Al) and ITO, and may be formed in a single-layered structure or a multi-layered structure, but is not limited thereto.

A bank 154 may be formed to cover an edge of the anode electrode 151 and expose at least one region of the anode electrode 151 toward an upper portion. The bank 154 is formed to define an opening (or the light emitting region EA) of the sub-pixel SP. That is, the region of the anode electrode 151 not covered but exposed by the bank 154 may define the light emitting region of the sub-pixel SP.

The bank 154 may be formed of an organic material such as a material including a black pigment and the like, a benzocyclobutene resin, a polyimide resin, an acrylic resin, or photosensitive polymer, but the embodiments of the present disclosure are not limited thereto. When the bank 154 is formed of a material including a black pigment, a black dye and the like, the bank 154 may be a black bank. When forming the bank 154 with a material including a black pigment, a black dye and the like, the bank 154 may block light from the outside or light reflected from the outside, thereby further improving luminance of the display device.

A spacer 155 may be further disposed on the bank 154. The spacer 155 may be formed of the same material as a material of the bank 154, but the embodiments of the present disclosure are not limited thereto. The spacer 155 may suppress or prevent mark or scratch defects on the display panel 100 by preventing sagging of a mask when performing a mask process.

The organic layer 152 may be disposed on the exposed region of the anode electrode 151 which is not covered by the bank. In other words, the organic layer 152 may be disposed on the exposed anode electrode 151 exposed by the bank 154. In another embodiment, the organic layer 152 may be disposed on an entire surface of the substrate.

The organic layer 152 may include one or more light emitting structures (or light emitting diode or an element) deposited on the anode electrode 151 in the order of a hole transfer layer and an electron transfer layer, or in the reverse order. For example, the hole transfer layer may include a hole transport layer, a hole injection layer, an electron blocking layer, a P-type electric charge generation layer and the like, but the embodiments of the present disclosure are not limited thereto. For example, the electron transfer layer may include an electron transport layer, an electron injection layer, a hole blocking layer, an N-type electric charge generation layer and the like, but the embodiments of the present disclosure are not limited thereto.

The organic layer 152 may be an organic light emitting layer, an inorganic light emitting layer, a quantum dot light emitting layer, a micro light emitting diode, a micro-mini light emitting diode and the like, but the embodiments of the present disclosure are not limited thereto. For example, the organic layer 152 of the display panel 50 according to an embodiment of the present disclosure may include an organic light emitting layer. The organic layer 152 may include a red light emitting layer, a green light emitting layer, and a blue light emitting layer, but is not limited thereto. The organic layer 152 may further include a white light emitting layer, but is not limited thereto.

The cathode electrode 153 may be disposed on the organic layer 152. The cathode electrode 153 may be a transparent electrode which transmits light, but the embodiments of the present disclosure are not limited thereto. For example, the cathode electrode 153 may include a transparent conductive material or metal such as Indium Tin Oxide (ITO) or Indium Zinc Oxide (IZO) through which the visible light is transmitted, but is not limited thereto.

A capping layer 156 may be further disposed on the cathode electrode 153. The capping layer 156 may minimize damage caused by an external light source to the cathode electrode 153 of the light emitting diode EL and the organic layer 152 below the cathode electrode 153. The capping layer 156 may be formed as an organic or inorganic layer.

The capping layer 156 may be disposed by using a material such as lithium fluoride (LiF) and the like as an inorganic layer, and may further include an organic layer, but the embodiments of the present disclosure are not limited thereto. For example, the capping layer 156 may be formed in a deposition structure in which an inorganic layer and an organic layer are deposited, and a thickness of the organic layer and a thickness of the inorganic layer may be different from each other. In such a case, the thickness of the organic layer may be greater than the thickness of the inorganic layer. As another example, the capping layer 156 may have two or more layers formed by depositing materials having different refractive indices. By doing so, the luminous efficiency of the display panel 50 can be improved.

The encapsulation unit 170 may be disposed on the bank 154 or the light emitting diode LD. The encapsulation unit 170 may include one or more insulation layers. For example, the encapsulation unit 170 may include a first inorganic encapsulation layer 171, a organic encapsulation layer 172 disposed on the first inorganic encapsulation layer 171, and a second inorganic encapsulation layer 173 disposed on the organic encapsulation layer 172. The encapsulation unit 170 may include one or more inorganic material layers and one or more organic material layers. For example, the first inorganic encapsulation layer 171 and the second inorganic encapsulation layer 173 may include an inorganic material, and the organic encapsulation layer 172 may include an organic material, but are not limited thereto.

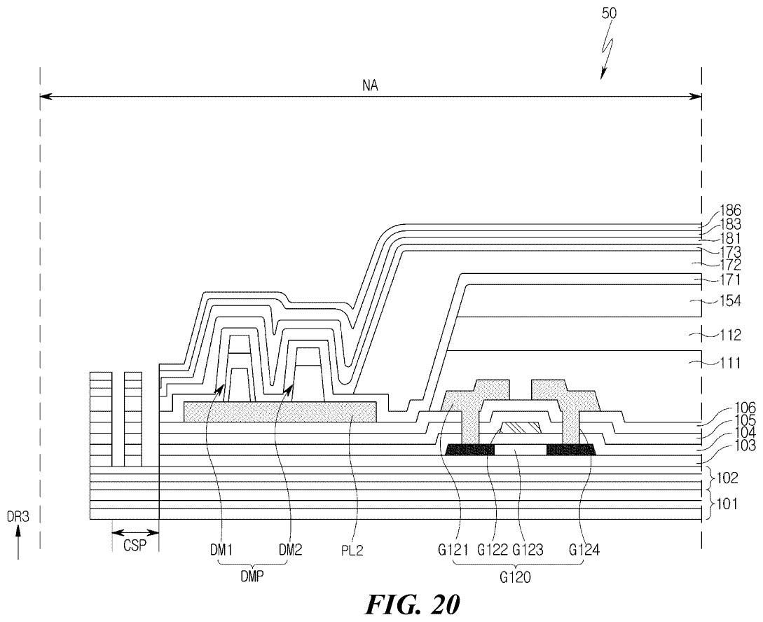

Even if the first inorganic encapsulation layer 171 and the second inorganic encapsulation layer 173 are disposed to extend up to an end of the non-display region NA, the organic encapsulation layer 172 may terminate on an inside of a dam portion DMP (FIG. 20). In other words, the organic encapsulation layer 172 may not cross the dam portion DMP, and may be disposed on an inside of a region surrounded by the dam portion DMP.

The touch unit 180 may be disposed on the encapsulation unit 170. The touch unit 180 may include a touch buffer layer 181, a first touch electrode 182, a first touch insulation layer 183, a black matrix BM, a second touch insulation layer 184, a second touch electrode 185, and a third touch insulation layer 186.

A touch buffer layer 181 may be disposed on the encapsulation unit 170. For example, the touch buffer layer 181 may be disposed on the second inorganic encapsulation layer 173. The touch buffer layer 181 may be formed of the same material as the buffer layer 102, but is not limited thereto.

The first touch electrode 182 may be disposed on the touch buffer layer 181.

The first touch insulation layer 183 may be disposed on the first touch electrode 182. The first touch insulation layer 183 may be formed of silicon oxide SiOₓ or silicon nitride SiNₓ, or formed in a muti-layered structure of silicon oxide SiOₓ and silicon nitride SiNₓ, but is not limited thereto.

The black matrix BM may be disposed on the first touch insulation layer 183. The black matrix BM may include a material which can absorb the light. The black matrix BM may include a black pigment or a black dye, but is not limited thereto. The black matrix BM may prevent a light leakage defect and the like which may occur between the sub-pixels SP.

The second touch insulation layer 184 may be disposed on the black matrix BM. The second touch insulation layer 184 may include an organic insulation material. For example, the second touch insulation layer 184 may be formed of photo acryl, benzocyclobutene (BCB), polyimide (PI), or polyamide (PA), but is not limited thereto.

The second touch electrode 185 may be disposed on the second touch insulation layer 184. The first touch electrode 182 and the second touch electrode 185 may include a metal material. For example, the first touch electrode 182 and the second touch electrode 185 may be formed of titanium (Ti), nickel (Ni), aluminum (Al), or an alloy thereof, and may be formed in a three-layered structure of titanium (Ti)/aluminum (Al)/titanium (Ti), but are not limited thereto.

One among the first touch electrode 182 and the second touch electrode 185 may include a function of sensing a touch, and the other thereamong may include a driving function of the touch, but are not limited thereto.

The third touch insulation layer 186 may be disposed on the second touch electrode 185. The third touch electrode 186 may include the same material as the first touch insulation layer 183, but is not limited thereto.

A microlens ML may be disposed on the third touch insulation layer 186. The microlens ML may have a hemispherical shape or a semicircular shape, but is not limited thereto. A shape of the microlens ML may vary according to a size and a shape of the light emitting region EA.

By disposing the microlens ML, it is possible to secure a wide viewing angle characteristic, improve luminance, and block leaking light, reflected light and the like, thereby preventing the light leakage.

A center of the microlens ML may be aligned with a center of the light emitting region EA corresponding thereto. However, the present embodiment is not limited thereto. In another embodiments, the center of the microlens ML may be mis-aligned with the center of the light emitting region EA corresponding thereto. In such an embodiment, optical components configured to output light emitted from the light emitting diode LD in a direction of the microlens ML may be further disposed. Alternatively, the light emitted from the light emitting diode LD may be output in the direction of the microlens ML as some components of the light emitting diode LD are tilted.

In the illustrated embodiment, the microlens ML is the first lens 501 (FIG. 14) having the hemispherical shape disposed in the first sub-pixel SP. However, the microlens ML is not limited thereto, and the microlens ML may be configured as the second lens 502 (FIG. 14) having the semicylindrical shape disposed in the second sub-pixel SP.

A lens protection layer 190 may be disposed on the microlens ML. The lens protection layer 190 may include an organic insulation material, but is not limited thereto. The lens protection layer 190 may protect the microlens ML by covering the microlens ML.

A refractive index of the lens protection layer 190 may be smaller than that of the microlens ML. Thus, due to a difference between the refractive indices of the microlens ML and the refractive index of the lens protection layer 190, it becomes possible to prevent light which passes through the microlens ML from being reflected in a direction of the substrate 101.

FIG. 20 is a cross-sectional view schematically illustrating the non-display region of the display panel according to an embodiment. In describing FIG. 20, the same content as provided for describing the cross-sectional structure of the display region AA of FIG. 19 will be briefly described or omitted.

Referring to FIG. 20, in the non-display region NA, the display panel 50 may include the substrate 101, the buffer layer 102, the first insulation layer 103, the second insulation layer 104, the third insulation layer 105, the fourth insulation layer 106, the first protection layer 111, the second protection layer 112, the bank 154, the encapsulation unit 170, the touch buffer layer 181, the first touch insulation layer 183, and the third touch insulation layer 186, which are sequentially disposed.

In the non-display region NA, the display panel 50 may further include a gate control transistor G120, a low potential voltage line VSSL, the dam portion DMP, and an anti-crack pattern CSP.

The gate control transistor G120 may have substantially the same configuration as the transistor 120 of the sub-pixel SP, and may be formed together with the transistor 120 of the sub-pixel SP through the same process, but is not limited thereto.

The gate control transistor G120 may include a control source electrode G121, a control gate electrode G122, a control semiconductor layer G123, and a control drain electrode G124.

The low potential voltage line VSSL may be disposed on the fourth insulation layer 106. The low potential voltage line VSSL may be disposed on the same layer as the source electrode 121 and the drain electrode 124, may include the same material as the source electrode 121 and the drain electrode 124, and may be formed together with the source electrode 121 and the drain electrode 124 using one mask through the same process, but is not limited thereto.

The dam portion DMP may include a first dam DM1 and a second dam DM2. The first dam DM1 and the second dam DM2 may overlap the low potential voltage line VSSL. The first dam DM1 may be disposed outside the second dam DM2, but is not limited thereto.

The first dam DM1 may be formed in a multi-layered structure. Each layer of the first dam DM1 may include the same material as the second protection layer 112, the bank 154, and the spacer 155, and may be formed together with the second protection layer 112, the bank 154, and the spacer 155 using one mask through the same process, but is not limited thereto.

The second dam DM2 may be formed in a multi-layered structure. Each layer of the second dam DM2 may include the same material as the second protection layer 112 and the bank 154, and may be formed together with the second protection layer 112 and the bank 154 using one mask through the same process, but is not limited thereto.

The anti-crack pattern CSP may be disposed at an edge position of the non-display region NA. The anti-crack pattern CSP may be defined by at least one recess formed in the inorganic layers disposed on the substrate 101.

For example, the anti-crack pattern CSP may be defined by at least one recess formed in the first insulation layer 103, the second insulation layer 104, the third insulation layer 105, the fourth insulation layer 106, the first inorganic encapsulation layer 171, the second inorganic encapsulation layer 173, the touch buffer layer 181, the first touch insulation layer 183, and the third touch insulation layer 186 are recessed, but is not limited thereto.

At least some of the inorganic layers disposed on the substrate 101 may extend up to the end of the non-display region NA. In other words, at least some of the inorganic layers disposed on the substrate 101 may extend up to an end of the substrate 101.

The buffer layer 102, the first insulation layer 103, the second insulation layer 104, the third insulation layer 105, the fourth insulation layer 106, the first inorganic encapsulation layer 171, the second inorganic encapsulation layer 173, the touch buffer layer 181, the first touch insulation layer 183, and the third touch insulation layer 186 may extend to the end of the non-display region NA.

In other words, in the non-display region NA, the buffer layer 102, the first insulation layer 103, the second insulation layer 104, the third insulation layer 105, the fourth insulation layer 106, the first inorganic encapsulation layer 171, the second inorganic encapsulation layer 173, the touch buffer layer 181, the first touch insulation layer 183, and the third touch insulation layer 186 may extend up to the end of the substrate 101.

In the non-display region NA, the buffer layer 102, the first insulation layer 103, the second insulation layer 104, the third insulation layer 105, the fourth insulation layer 106, the first inorganic encapsulation layer 171, the second inorganic encapsulation layer 173, the touch buffer layer 181, the first touch insulation layer 183, and the third touch insulation layer 186 may substantially cover the entire region of the substrate 101.

An end (or a side surface) of each of the substrate 101, the buffer layer 102, the first insulation layer 103, the second insulation layer 104, the third insulation layer 105, the fourth insulation layer 106, the first inorganic encapsulation layer 171, the second inorganic encapsulation layer 173, the touch buffer layer 181, the first touch insulation layer 183, and the third touch insulation layer 186 may be aligned with each other, but is not limited thereto.

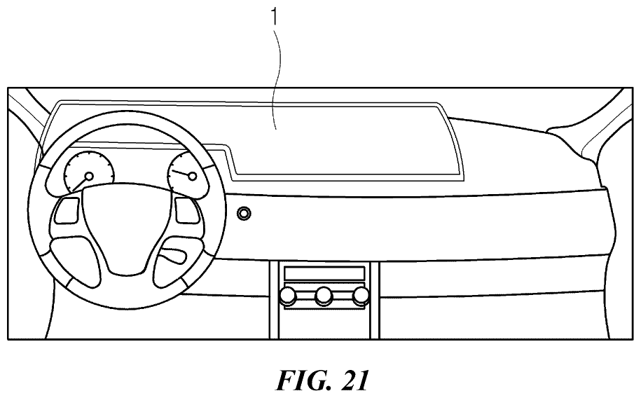

FIG. 21 is an example view of an arrangement of the display device according to an embodiment. More particularly, FIG. 21 shows a case in which the display device 1 is disposed in a vehicle in greater detail.

Referring to FIG. 21, the display device 1 may be disposed in at least some portion of a dashboard of a vehicle. The dashboard of a vehicle includes a configuration disposed on a front surface of front seats of a vehicle (for example, a driver's seat, and a front passenger's seat). For example, in the dashboard of a vehicle, an input configuration for manipulating various functions inside a vehicle (for example, an air-conditioner, an audio system, a navigation system) may be disposed.

In an embodiment, the display device 1 may be disposed on the dashboard of a vehicle, and may operate as an input part configured to manipulate at least some of the various functions of a vehicle. The display device 1 may provide various information related to the vehicle, for example, traveling information of the vehicle (e.g., a current velocity, a remaining fuel amount, a traveled distance of the vehicle), and information of parts of the vehicle.

The display device 1 may be disposed to traverse the driver's seat and the front passenger's seat disposed on a front side of the vehicle as illustrated. Users of the display device 1 may include a driver and a passenger seated on the front passenger's seat. That is, both the driver and the passenger may use the display device 1.

In an embodiment, the display device 1 may be divided into a plurality of regions. For example, the display device may be divided into a first region A1 and a second region A2. Division into the first region A1 and the second region A2 may be division of regions in which contents are displayed in the display region of the display device 1. That is, the first region A1 may display the first image, and the second region A2 may display the second image. In an embodiment, the first region A1 may be disposed close to the driver, and the second region A2 may be disposed close to the front passenger's seat, but are not limited thereto.

The display device 1 shown in FIG. 21 may correspond to at least some of the display panel 50 (FIG. 2) included in the display device 1. For example, the display device 1 illustrated in FIG. 21 may show at least some of the display region AA (FIG. 2) and the non-display region NA (FIG. 2) of the display panel 50. Other components except a portion illustrated in FIG. 21 among the components of the display device 1 may be mounted inside the vehicle.

The embodiments of the present disclosure have been described with reference to accompanying drawings. Those of ordinary skill in the art will recognize that the present disclosure may be embodied in other specific forms without departing from its spirit or essential characteristics. The described embodiments are to be considered in all respects only as illustrative and not restrictive. The scope of the present disclosure includes those of the appended claims. All changes which come within meaning and range of equivalency of the claims are to be embraced within the scope of the present disclosure.

The various embodiments described above can be combined to provide further embodiments. Aspects of the embodiments can be modified, if necessary to employ concepts of the various embodiments to provide yet further embodiments.

These and other changes can be made to the embodiments in light of the above-detailed description. In general, in the following claims, the terms used should not be construed to limit the claims to the specific embodiments disclosed in the specification and the claims, but should be construed to include all possible embodiments along with the full scope of equivalents to which such claims are entitled. Accordingly, the claims are not limited by the disclosure.

1. A display device, comprising:
a display panel on which a plurality of pixels are disposed;
a data driver configured to provide a data voltage to the plurality of pixels through a plurality of data lines; and
a multiplexer connected between the data driver and the plurality of data lines and including a plurality of switching elements connected to be controlled by a plurality of mux control signals,
wherein each of the plurality of pixels comprises:
a first sub-pixel configured to display a first image; and
a second sub-pixel configured to display a same color as the first sub-pixel and to display a second image different from the first image.

2. The display device of claim 1,
wherein the data driver includes:
an output buffer configured to output the data voltage to an output channel,
wherein the multiplexer includes:
a first switching element configured to be turned on in response to a first mux control signal and connect the output channel to the first sub-pixel; and
a second switching element configured to be turned on in response to a second mux control signal and connect the output channel to the second sub-pixel.

3. The display device of claim 2,
wherein the output buffer is configured to output a first data voltage corresponding to the first image in synchronization with the first mux control signal while the pixel is operated in a first mode; and
wherein the output buffer is configured to output a second data voltage corresponding to the second image in synchronization with the second mux control signal while the pixel is operated in a second mode.

4. The display device of claim 3,
wherein the output buffer is configured to output a dummy data voltage in synchronization with the second mux control signal while the pixel is operated in the first mode, and
wherein the output buffer is configured to output the dummy data voltage in synchronization with the first mux control signal while the pixel is operated in the second mode.

5. The display device of claim 1,
wherein the data driver includes:
a first output buffer configured to output a first data voltage corresponding to the first image to a first output channel; and
a second output buffer configured to output a second data voltage corresponding to the second image to a second output channel,
wherein the first output channel is connected to the first sub-pixel, and
wherein the second output channel is connected to the second sub-pixel.

6. The display device of claim 5,
wherein the first output buffer is configured to output a first data voltage corresponding to the first image to the first sub-pixel while the pixel is operated in a first mode, and
wherein the second output buffer is configured to output a second data voltage corresponding to the second image to the second sub-pixel while the pixel is operated in a second mode.

7. The display device of claim 6,
wherein the first output buffer is configured to output a dummy data voltage to the first sub-pixel while the pixel is operated in the first mode, and
wherein the first output buffer is configured to output the dummy data voltage to the second sub-pixel while the pixel is operated in the second mode.

8. The display device of claim 5,
wherein the multiplexer includes:
a first switching element configured to be turned on in response to a first mux control signal and connect the first output channel to the first sub-pixel; and
a second switching element configured to be turned on in response to the first mux control signal and connect the second output channel to the second sub-pixel.

9. The display device of claim 5,
wherein the display panel includes:
a plurality of unit pixels, each of which including a first pixel and a second pixel,
wherein the multiplexer includes:
a first switching element configured to be turned on in response to a first mux control signal and connect the first output channel to a first sub-pixel of the first pixel;
a second switching element configured to be turned on in response to the first mux control signal and connect the second output channel to a second sub-pixel of the first pixel;
a third switching element configured to be turned on in response to a second mux control signal and connect the first output channel to a first sub-pixel of the second pixel; and
a fourth switching element configured to be turned on in response to the second mux control signal and connect the second output channel to a second sub-pixel of the second pixel.

10. The display device of claim 1,
wherein the display panel includes:
a first region in which the first image is configured to be displayed through the first sub-pixel of the plurality of pixels; and
a second region in which the second image is configured to be displayed through the second sub-pixel of the plurality of pixels, and
wherein the first region and the second region vary while the display panel is driven.

11. The display device of claim 10,
wherein in the first region, the second sub-pixel outputs a dummy image, and
wherein in the second region, the first sub-pixel outputs the dummy image.

12. The display device of claim 1,
wherein the first sub-pixel and the second sub-pixel have a same pixel structure, and
wherein the first sub-pixel and the second sub-pixel have a form mirrored along a pixel column direction.

13. The display device of claim 1, further comprising:
a lens member disposed on the display panel and including a plurality of lenses,
wherein the lens member includes:
a first lens disposed in a first light emitting region of the first sub-pixel; and
a second lens disposed in a second light emitting region of the second sub-pixel and having a form different from the first lens.

14. The display device of claim 13,
wherein the first lens is configured to control a light emitted from the first light emitting region to be emitted at a first viewing angle, and
wherein the second lens is configured to control a light emitted from the second light emitting region to be emitted at a second viewing angle.

15. A method for driving a display device, wherein the display device includes:
a display panel on which a plurality of pixels being disposed;
a data driver configured to provide a data voltage to a plurality of data lines connected to the plurality of pixels through a plurality of output channels; and
a multiplexer connected between the data driver and the plurality of data lines and including a plurality of switching elements connected to be controlled by a plurality of mux control signals, with each of the plurality of pixels comprising:
a first sub-pixel configured to display a first image; and
a second sub-pixel configured to display a same color as the first sub-pixel and display a second image different from the first image,
the method comprising:
controlling the data driver to output a first data voltage corresponding to the first image to the first sub-pixel; and
controlling the data driver to output a second data voltage corresponding to the second image to the second sub-pixel.

16. The method of claim 15,
wherein the outputting the first data voltage includes:
controlling the multiplexer to connect a first output channel to the first sub-pixel in response to a first mux control signal in a first period of one horizontal period;
controlling the data driver to output the first data voltage in synchronization with the first mux control signal in the first period;
controlling the multiplexer to connect the first output channel to the second sub-pixel in response to a second mux control signal in a second period of the one horizontal period; and
controlling the data driver to output a dummy data voltage in synchronization with the second mux control signal in the second period.

17. The method of claim 15,
wherein the outputting the second data voltage includes:
controlling the multiplexer to connect a first output channel to the first sub-pixel in response to a first mux control signal in a first period of one horizontal period;
controlling the data driver to output the dummy data voltage in synchronization with the first mux control signal in the first period;
controlling the multiplexer to connect the first output channel to the second sub-pixel in response to a second mux control signal in a second period of the one horizontal period; and
controlling the data driver to output the second data voltage in synchronization with the second mux control signal in the second period.

18. The method of claim 15,
wherein the display panel includes:
a plurality of unit pixels, each of which including a first pixel and a second pixel,
wherein the outputting the first data voltage includes:
controlling the multiplexer to connect a first output channel to the first sub-pixel of the first pixel in response to a first mux control signal in a first period of one horizontal period; and
controlling the data driver to output the first data voltage to the first output channel in synchronization with the first mux control signal in the first period, and
wherein the outputting a second data voltage includes:
controlling the multiplexer to connect the second output channel to the second sub-pixel of the first pixel in response to the first mux control signal in the first period; and
controlling the data driver to output the second data voltage to the second output channel in synchronization with the first mux control signal in the first period.

19. The method of claim 18,
wherein the outputting the first data voltage includes:
controlling the multiplexer to connect the first output channel to the first sub-pixel of the second pixel in response to a second mux control signal in a second period of the one horizontal period; and
controlling the data driver to output the first data voltage to the first output channel in synchronization with the second mux control signal in the second period, and
wherein the outputting a second data voltage includes:
controlling the multiplexer to connect the second output channel to the second sub-pixel of the second pixel in response to the second mux control signal in the second period; and
controlling the data driver to output the second data voltage to the second output channel in synchronization with the second mux control signal in the second period.

20. The method of claim 15,
wherein the outputting the first data voltage includes:
controlling the data driver to output the first data voltage to the first sub-pixel through a first output channel in a first horizontal period, and
wherein the outputting a second data voltage includes:
controlling the data driver to output the second data voltage to the second sub-pixel through a second output channel in the first horizontal period.

21. A display device, comprising:
a display panel on which a plurality of unit pixels being disposed;
a data driver configured to provide a data voltage to the plurality of unit pixels through a plurality of data lines; and
a multiplexer connected between the data driver and the plurality of data lines and including a plurality of switching elements connected to be controlled by a plurality of mux control signals,
wherein each of the plurality of unit pixels includes a plurality of pixels,
wherein each of the plurality of pixels comprises:
a first sub-pixel configured to emit light at a first luminance corresponding to a first image; and
a second sub-pixel configured to emit light of the same color as the first sub-pixel at a second luminance different from the first luminance corresponding to a second image,
wherein the first sub-pixel and the second sub-pixel are time-dividedly driven during one horizontal period.

22. A display device, comprising:
a display panel on which a plurality of pixels are disposed; and
a data driver including a plurality of output buffers configured to provide a data voltage to the plurality of pixels,
wherein each of the plurality of pixels comprises:
a first sub-pixel connected to an output buffer through a first switch; and
a second sub-pixel connected to the output buffer through a second switch, the second sub-pixel configured to display a same color as the first sub-pixel; and
wherein the first switch and the second switch are configured to have opposite switching states.

23. The display device of claim 22, comprising:
a first lens on a light emitting region of the first sub-pixel; and
a second lens on a light emitting region of the second sub-pixel,
wherein the first lens is configured to emit light at a first angle, and the second lens is configured to emit light at a second angle different from the first angle.

24. The display device of claim 23, wherein the first lens is a hemispherical lens, and has a cross-section having a semicircular shape.

25. The display device of claim 23, wherein the second lens is a semicylindrical lens, and has a rectangular shape in a first cross-section and a semicircular shape in a second cross-section.
